(19) United States
(12) Patent Application Publication
(10) Pub. No.: US 2025/0123220 A1
(43) Pub. Date: Apr. 17, 2025

(54) Defect Inspection Apparatus and Defect Inspection Method

(71) Applicant: Hitachi High-Tech Corporation, Minato-ku, Tokyo (JP)

(72) Inventors: Takanori KONDO, Tokyo (JP); Yuta TAGAWA, Tokyo (JP); Toshifumi HONDA, Tokyo (JP); Yuta URANO, Tokyo (JP)

(21) Appl. No.: 18/834,081

(22) PCT Filed: Feb. 9, 2022
(86) PCT No.: PCT/JP2022/005225

§ 371 Date: Jul. 29, 2024

(51) Int. Cl. G01N 21/95; G01N 21/88

(52) U.S. Cl. CPC G01N 21/9501; G01N 21/8851; G01N 2201/021

(57) ABSTRACT

This defect inspecting device comprises a sample stage for supporting a sample, an illuminating optical system for emitting illuminating light onto the sample placed on the sample stage, a scanning device for changing a relative position of the sample and the illuminating optical system by rotationally driving the sample stage, a plurality of detecting optical systems for condensing light from a surface of the sample, a plurality of sensors for converting the light condensed by the corresponding detecting optical system into an electrical signal and outputting a detection signal, and a signal processing device for processing the detection signals from the plurality of sensors to detect a defect in the sample, wherein, by employing this defect inspecting device, when inspecting a sample having a structure formed repeatedly on a surface thereof, the detection signal of the structure is eliminated or reduced, and diffracted light generated by the structure, or the detection signal thereof, is eliminated or reduced either in accordance with a e coordinate of a circular coordinate system of the sample, or with a set period.

### TECHNICAL FIELD

The present invention relates to a semiconductor defect inspection apparatus and a defect inspection method.

### BACKGROUND ART

In a manufacturing line for a semiconductor substrate, a thin film substrate, or the like, a defect on a surface of the semiconductor substrate, thin film substrate, or the like is inspected in order to improve product yield. As a defect inspection apparatus used for this defect inspection, an inspection apparatus is known that irradiates a sample with light rays and detects a defect by detecting light rays from the surface of the sample with a sensor (see PTL 1, and the like).

### CITATION LIST

### Patent Literature

PTL 1: JP2011-013058A

### SUMMARY OF INVENTION

### Technical Problem

In addition to a type (hereinafter referred to as an XY scanning method) of scanning a sample in a vertical and horizontal direction (X and Y directions), defect inspection apparatuses include a type (hereinafter referred to as a rotational scanning method) of scanning a sample by rotating the sample in a circumferential direction (θ direction) and moving the sample in a radial direction (r direction). The defect inspection apparatus disclosed in PTL 1 is an example of the rotational scanning method. Compared to the XY scanning method in which a stage is reciprocated during scanning and the stage is repeatedly accelerated and decelerated, the rotational scanning method is advantageous in terms of throughput. However, it is difficult to simply apply a defect inspection apparatus with the rotational scanning method to inspecting a sample (for example, a patterned wafer) of which a surface has a large number of fine structures formed in a grid pattern.

For example, when inspecting a wafer with a semiconductor pattern on which many fine structures are formed in a grid pattern, it is necessary to distinguish signals from normally formed fine structures (for example, a die or a circuit pattern therein) from detection signals of defects. In the case of the XY scanning method, the die formed on the surface of a semiconductor wafer and the circuit pattern inside it are repeated in the X and Y directions, so by comparing signals from areas with the same shape, signals from the circuit pattern can be removed and defect detection signals can be extracted. However, in the case of the rotational scanning method, since an angle of the circuit pattern at an illumination spot changes as a sample rotates during it scanning, is difficult to distinguish a detection signal from a pattern from a detection signal of a defect by comparing the areas.

An object of the present invention is to provide a defect inspection apparatus and a defect inspection method that can accurately inspect a sample having such fine structures (for example, die and circuit patterns within it) repeatedly formed on its surface using a rotational scanning method.

### Solution to Problem

In order to achieve the above-described object, the present invention provides a defect inspection apparatus that inspects a sample with a structure repeatedly formed on a surface, the apparatus including a sample stand supporting the sample, an illumination optical system that irradiates the sample placed on the sample stand with an illumination light ray, a scanning device that rotationally drives the sample stand to change a relative position of the sample and the illumination optical system, a plurality of detection optical systems that collect light rays from the surface of the sample, a plurality of sensors that convert the light rays collected by the corresponding detection optical systems into electrical signals and output detection signals, a signal processing device that processes the detection signals of the plurality of sensors to detect a defect in the sample, a first filter that removes or reduces the detection signals of the structure, and a second filter that removes or reduces diffracted light rays generated by the structure or detection signals of the diffracted light rays according to a θ coordinate of a circular coordinate system of the sample or at a set period.

### Advantageous Effects of Invention

According to the present invention, a sample in which fine structures are repeatedly formed on a surface can be accurately inspected using a rotational scanning method. By performing defect inspection using the rotational scanning method capable of performing inspections faster than an XY scanning method, throughput can be improved, inspection time can be shortened, and inspection cost per one sample can be reduced.

### BRIEF DESCRIPTION OF DRAWINGS

FIG. 1 is a schematic diagram of a configuration example of a defect inspection apparatus according to the present invention.

FIG. 2 is a schematic diagram illustrating a scanning trajectory of a sample.

FIG. 3 is a schematic diagram (comparative example) illustrating a scanning trajectory of a sample.

FIG. 4 is a schematic diagram illustrating an attenuator extracted.

FIG. 5 is a schematic diagram illustrating a positional relationship between an optical axis of an illumination light ray guided obliquely to a surface of the sample and an illumination intensity distribution shape.

FIG. 6 is a schematic diagram illustrating a positional relationship between an optical axis of an illumination light ray guided obliquely to a surface of the sample and an illumination intensity distribution shape.

FIG. 7 is a diagram illustrating an area where a detection optical system collects scattered light rays when viewed from above.

FIG. 8 is a diagram schematically illustrating detection zenith angles of the low-angle and high-angle detection optical systems.

FIG. 9 is a plan view illustrating a detection azimuth angle of the low-angle detection optical system.

FIG. 10 is a plan view illustrating a detection azimuth angle of the high-angle detection optical system.

FIG. 11 is a schematic diagram illustrating an example of a configuration diagram of the detection optical system.

FIG. 12 is a schematic diagram illustrating an example of a detection map when a patterned wafer is measured by a defect inspection apparatus with a rotational scanning method.

FIG. 13 is a schematic diagram illustrating an example of a detection map when a patterned wafer is measured by a defect inspection apparatus with a rotational scanning method.

FIG. 14 is a schematic diagram illustrating a relationship between an emission direction of diffracted light rays generated by a pattern and an angle of the sample.

FIG. 15 is a diagram illustrating an intersection line of a spherical surface centered on an irradiation spot and a conical surface related to a traveling direction of a diffracted light ray projected onto an xy plane.

FIG. 16 is a schematic diagram illustrating a change in rotation angle of the sample with respect to an illumination light ray.

FIG. 17 is a schematic diagram illustrating a change in rotation angle of the sample with respect to an illumination light ray.

FIG. 18 is a schematic diagram illustrating a change in an emission direction of a diffracted light ray depending on a rotation angle of the sample.

FIG. 19 is a schematic diagram illustrating a change in an emission direction of a diffracted light ray depending on a rotation angle of the sample.

FIG. 20 is a schematic diagram illustrating an example of pattern mask data applied to a defect inspection apparatus according to a first embodiment of the present invention.

FIG. 21 is a schematic diagram illustrating an example of haze data (in map form) applied to the defect inspection apparatus according to the first embodiment of the present invention.

FIG. 22 is a flowchart illustrating a defect inspection procedure of the defect inspection apparatus according to the first embodiment of the present invention.

FIG. 23 is a flowchart illustrating a defect inspection procedure of a defect inspection apparatus according to a second embodiment of the present invention.

FIG. 24 is a functional block diagram of a second filter of a defect inspection apparatus according to a third embodiment of the present invention.

FIG. 25 is a schematic diagram illustrating main parts of a defect inspection apparatus according to a fourth embodiment of the present invention.

FIG. 26 is a schematic diagram illustrating a configuration example of a second filter provided in the defect inspection apparatus according to the fourth embodiment of the present invention.

FIG. 27 is a schematic diagram illustrating main parts of a defect inspection apparatus according to a fifth embodiment of the present invention.

FIG. 28 is a schematic diagram illustrating an incident range of diffracted light rays with respect to a detection aperture in a comparative example (when the second filter is omitted in the fifth embodiment).

FIG. 29 is a graph illustrating a relationship of detection sensitivity of a detection optical system and the number of effective sensors with respect to an incident azimuth angle for the comparative example in FIG. 28.

FIG. 30 is a graph illustrating a relationship of detection sensitivity of a detection optical system and the number of effective sensors with respect to an incident azimuth angle for the example (fifth embodiment) in FIG. 27.

FIG. 31 is a functional block diagram illustrating an example of pattern mask data generation processing in a defect inspection apparatus according to a sixth embodiment of the present invention.

FIG. 32 is a diagram illustrating an example of haze data used in the defect inspection apparatus according to the sixth embodiment of the present invention.

FIG. 33 is a diagram illustrating an example of a foreign matter map used in a defect inspection apparatus according to a seventh embodiment of the present invention.

FIG. 34 is a schematic diagram illustrating main parts of a defect inspection apparatus according to a modification example of the present invention.

FIG. 35 is a schematic diagram illustrating main parts of a defect inspection apparatus according to another modification example of the present invention.

### DESCRIPTION OF EMBODIMENTS

Embodiments of the present invention will be described below using the drawings.

A defect inspection apparatus to be described as an object to which the present invention is applied in the following embodiments is used, for example, for defect inspection of a sample (semiconductor silicon wafer) during a manufacturing process of a semiconductor or the like. In particular, the defect inspection apparatus of this embodiment is suitable for inspecting wafers (patterned wafers) in which a large number of fine structures, such as semiconductor circuit patterns, are repeatedly formed on a surface at fine pitches. With the defect inspection apparatus according to each embodiment, it is possible to detect minute defects in a sample and to obtain data regarding the number, position, size, and type of defects at high speed.

### First Embodiment

### Defect Inspection Apparatus

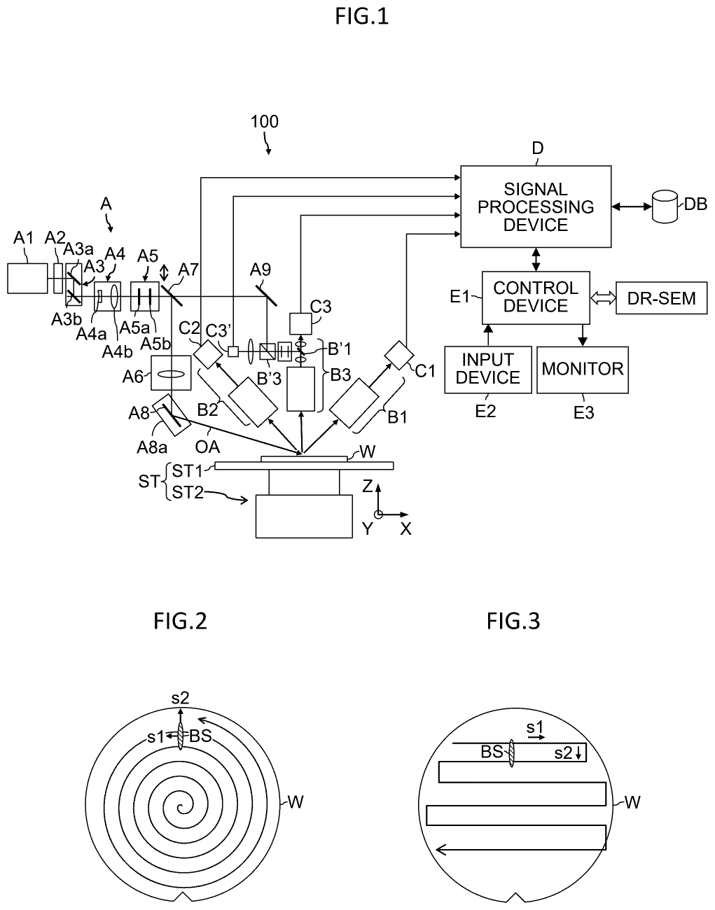

FIG. 1 is a schematic diagram of a configuration example of a defect inspection apparatus 100 according to the present embodiment. An XYZ orthogonal coordinate system with a Z axis extending in a vertical direction is defined as shown in FIG. 1. The defect inspection apparatus 100 takes a sample W as an inspection target and detects defects such as abnormal film formation, abnormal pattern formation, and adhesion of foreign matters on a surface of the sample W. The defect inspection apparatus 100 is an apparatus with rotational scanning method of scanning the sample W by rotating the sample in a circumferential direction (θ direction) and moving the sample in a radial direction (r direction).

The defect inspection apparatus 100 has been often used to inspect wafers (substrates) on which no patterns are formed. However, in each embodiment of the present invention, a case will be exemplified in which a patterned wafer in which dies are formed in a matrix (arranged in x and y directions of the xy orthogonal coordinate system on the sample) on a surface of a substrate is inspected. On each die, a fine circuit pattern (fine structure) is repeatedly formed in the same way at a fine pitch.

The defect inspection apparatus 100 includes a stage ST, an illumination optical system A, a plurality of detection optical systems B1 to Bn (n=1, 2 . . . ), sensors C1 to Cn and C1′ to Cn′ (n=1, 2 . . . ), a signal processing device D, a storage device DB, a control device E1, an input device E2, and a monitor E3.

### Stage

The stage ST is a device that includes a sample stand ST1 and a scanning device ST2. The sample stand ST1 is a stand that supports the sample W. The scanning device ST2 is a device that drives the sample stand ST1 to change a relative position of the sample W and the illumination optical system A, and although detailed illustration is omitted, the scanning device is configured to include a translation stage, a rotation stage, and a Z stage. The rotation stage is mounted on the translation stage via the Z stage, and the sample stand ST1 is supported on the rotation stage. The translation stage translates in a horizontal direction together with the rotation stage. The rotation stage rotates (rotates) around a rotation axis extending vertically. The Z stage functions to adjust the height of the surface of the sample W.

FIG. 2 is a schematic diagram illustrating a scanning trajectory of the sample W by the scanning device ST2. As will be described below, an illumination spot BS, which is an incident area of an illumination light ray emitted from the illumination optical system A onto the surface of the sample W, is a minute point having a long illumination intensity distribution in one direction, as illustrated in the figure. A long axis direction of the illumination spot BS is s2, and a direction (for example, a short axis direction perpendicular to the long axis) intersecting the long axis is s1. The sample W rotates as the rotation stage rotates, and the illumination spot BS is scanned in the s1 direction relative to the surface of the sample W, and then as the translation stage translates, the sample W moves in the horizontal direction, and the illumination spot BS is scanned in the s2 direction relative to the surface of the sample W. The illumination spot BS moves in the s2 direction by a distance equal to or less than the length of the illumination spot BS in the s2 direction while the sample W rotates once. As the sample W is translated while rotating due to the operation of the scanning device ST2, as illustrated in FIG. 2, the illumination spot BS moves in a spiral trajectory from the center of the sample W to an outer edge or its vicinity, and the entire surface of the sample W is scanned.

There also generally exists a scanning device having a configuration in which instead of (or in addition to) the rotation stage, another translation stage of which a movement axis extends in a direction that intersects a movement axis of the translation stage in a horizontal plane is provided. In this case, as illustrated in FIG. 3, the illumination spot BS scans the surface of the sample W by folding a linear trajectory instead of a spiral trajectory. In the example in the same figure, a first translation stage is translated in the s1 direction at a constant speed, a second translation stage is driven in the s2 direction by a predetermined distance (for example, a distance that is equal to or less than the length of the illumination spot BS in the s2 direction), and then the first translation stage is turned back and translated in the s1 direction again. As a result, the illumination spot BS repeats linear scanning in the s1 direction and movement in the s2 direction, and scans the entire surface of the sample W. Compared to this XY scanning method, the rotational scanning method of this embodiment does not involve reciprocating motion that repeats acceleration and deceleration, so that the inspection time for the sample W can be shortened.

### Illumination Optical System

The illumination optical system A illustrated in FIG. 1 is configured to include a group of optical elements in order to irradiate the sample W placed on the sample stand ST1 with desired illumination light rays. As illustrated in FIG. 1, the illumination optical system A includes a laser light source A1, an attenuator A2, an emitted light adjustment unit A3, a beam expander A4, a polarization control unit A5, a condensing optical unit A6, reflection mirrors A7 to A9, and the like.

### Laser Light Source

The laser light source A1 is a unit that emits a laser beam as an illumination light ray. When detecting minute defects near the surface of the sample W with the defect inspection apparatus 100, a laser light source that oscillates a high-output laser beam of 2 W or more in ultraviolet or vacuum ultraviolet light with a short wavelength (wavelength of 355 nm or less) that is difficult to penetrate into the inside of the sample W is used as the laser light source A1. A diameter of the laser beam emitted by the laser light source A1 is typically about 1 mm. When the defect inspection apparatus 100 detects a defect inside the sample W, a laser light source that oscillates a visible or infrared laser beam that has a long wavelength and easily penetrates into the inside of the sample W is used as the laser light source A1.

### Attenuator

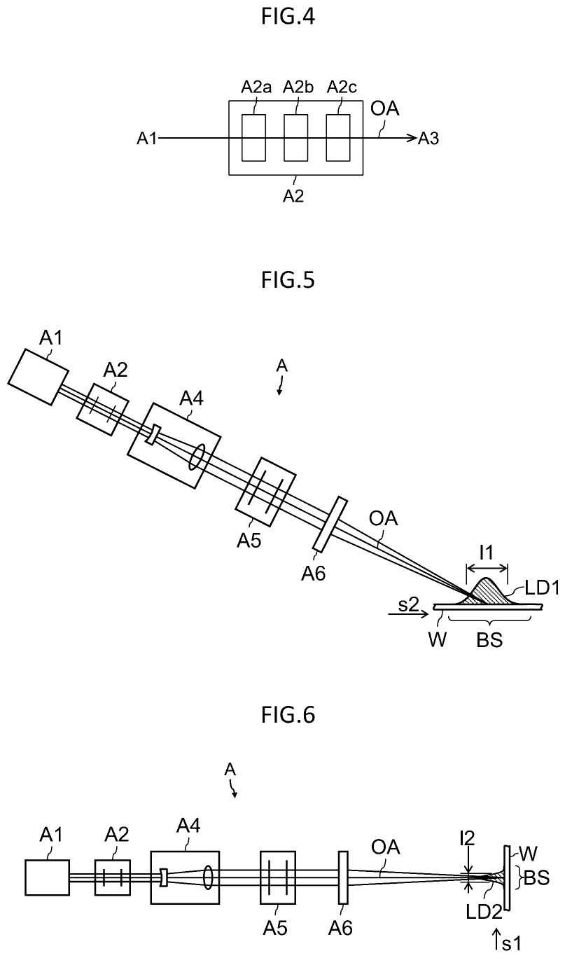

FIG. 4 is a schematic diagram illustrating the attenuator A2 extracted. The attenuator A2 is a unit that attenuates the light intensity of the illumination light ray from the laser light source A1, and in this embodiment, a configuration in which a first polarizing plate A2a, a half-wavelength plate A2b, and a second polarizing plate A2c are combined is illustrated. The half-wavelength plate A2b is configured to be rotatable around an optical axis of the illumination light ray. The illumination light ray incident on the attenuator A2 is converted into a linearly polarized light ray by the first polarizing plate A2a, and then a polarization direction is adjusted to a slow axis azimuth of the half-wavelength plate A2b and the light ray passes through polarizing plate A2c. By adjusting the azimuth of the half-wavelength plate A2b, the light intensity of the illumination light ray is attenuated at an arbitrary ratio. When the degree of linear polarization of the illumination light ray incident on the attenuator A2 is sufficiently high, the first polarizing plate A2a can be omitted. The attenuator A2 is one in which a relationship between an incident illumination light ray and a light attenuation rate is calibrated in advance. The attenuator A2 is not limited to the configuration illustrated in FIG. 4, and can also be configured using an ND filter with a gradation concentration distribution. Further, the attenuator A2 can have a configuration in which an attenuation effect can be adjusted by combining a plurality of ND filters with different concentrations.

### Emitted Light Adjustment Unit

The emitted light adjustment unit A3 illustrated in FIG. 1 is a unit that adjusts an angle of an optical axis of the illumination light ray attenuated by the attenuator A2, and in this embodiment, the emitted light adjustment unit A3 is configured to include a plurality of reflection mirrors A3a and A3b. The configuration is such that the illumination light ray is sequentially reflected by the reflection mirrors A3a and A3b. However, in this embodiment, an illumination light incidence/emission plane to the reflection mirror A3a is configured to be perpendicular to the illumination light incidence/emission plane to the reflection mirror A3b. The incidence/emission plane is a surface that includes an optical axis of a light ray that enters the reflection mirror and an optical axis of light ray that exits from the reflection mirror. When the configuration is such that the illumination light ray enters the reflection mirror A3a in a +X direction, although different from the schematic diagram of FIG. 1, for example, a traveling direction of the illumination light ray is changed in a +Y direction by the reflection mirror A3a, and then in a +Z direction by the reflection mirror A3b. In this example, the incidence/emission plane of the illumination light ray to the reflection mirror A3a is an XY plane, and the incidence/emission plane to the reflection mirror A3b is a YZ plane. The reflection mirrors A3a and A3b are provided with mechanisms (not illustrated) that respectively translate and tilt the reflection mirrors A3a and A3b. For example, the reflection mirrors A3a and A3b move in parallel in the incident direction or the emission direction of the illumination light ray with respect to themselves, and tilt around the normal line to the incidence/emission planes. As a result, for example, regarding the optical axis of the illumination light ray emitted from the emitted light adjustment unit A3 in a +Z direction, it is possible to independently adjust the offset amount and angle in an XZ plane and the offset amount and angle in a YZ plane. In this example, a configuration using two reflection mirrors A3a and A3b is illustrated, but a configuration using three or more reflection mirrors is also possible.

### Beam Expander

The beam expander A4 is a unit that expands a light flux diameter of the incident illumination light ray, and has a plurality of lenses A4a and A4b. An example of the beam expander A4 is a Galileo type in which a concave lens is used as the lens A4a and a convex lens is used as the lens A4b. The beam expander A4 is equipped with a distance adjustment mechanism (zoom mechanism) between lenses A4a and A4b, and by adjusting the distance between lenses A4a and A4b, an expansion rate of the light flux diameter is changed. The expansion rate of the light flux diameter by the beam expander A4 is, for example, about 5 times to 10 times. In this case, assuming that the beam diameter of the illumination light ray emitted from the laser light source A1 is 1 mm, the beam system of the illumination light rays is expanded to about 5 mm to 10 mm. When the illumination light rays incident on the beam expander A4 are not parallel light flux, it is possible to collimate (make the light flux semi-parallel) the diameter of the light flux by adjusting the distance between the lenses A4a and A4b. However, the collimation of the light flux may be performed using a collimating lens installed upstream of the beam expander A4 and separately from the beam expander A4.

The beam expander A4 is installed on a translation stage with two axes (two degrees of freedom) or more, and is configured so that its position can be adjusted so that its center coincides with the incident illumination light ray. In addition, the beam expander A4 is also equipped with a tilt angle adjustment function on two or more axes (two degrees of freedom) so that the incident illumination light ray and the optical axis coincide.

Further, although not particularly illustrated, a state of the illumination light ray incident on the beam expander A4 is measured by a beam monitor in the middle of the optical path of the illumination optical system A.

### Polarization Control Unit

The polarization control unit A5 is an optical system that controls a polarization state of the illumination light ray, and includes a half-wavelength plate A5a and a quarter-wavelength plate A5b. For example, when the reflection mirror A7, which will be described below, is placed in the optical path and the sample W is illuminated diagonally, by making the illumination light ray P-polarized by the polarization control unit A5, an amount of scattered light rays from defects on the surface of the sample W can be increased compared to polarized light rays other than P-polarized light rays. When there is a film structure on the surface of the sample W, depending on the material and thickness of the film, using S-polarized light rays can increase the amount of scattered light rays from defects more than P-polarized light rays. Further, scattered light rays (referred to as haze) generated by objects other than foreign matters on the surface of the sample W interferes with detecting the scattered light rays from the foreign matters. Haze is caused by diffraction due to minute irregularities (roughness and patterns) on the surface of the sample W and the film structure. By selecting the optimal polarization for the film structure of the sample W, it is possible to reduce haze and improve the sensitivity of foreign matter detection. It is also possible to make the illumination light rays into circularly polarized light rays or into 45-degree polarized light rays between P-polarized light rays and S-polarized light rays using the polarization control unit A5.

### Reflection Mirror

As illustrated in FIG. 1, the reflection mirror A7 is moved in parallel in a direction of the arrow by a drive mechanism (not illustrated), and enters and exits the optical path of illumination light rays directed toward the sample W. Thereby, the incident path of the illumination light rays to the sample W is switched. By inserting the reflection mirror A7 into the optical path, the illumination light rays emitted from the polarization control unit A5 as described above are reflected by the reflection mirror A7 and obliquely enter the sample W via the condensing optical unit A6 and the reflection mirror A8. In this specification, making illumination light rays incident on the sample W from a direction oblique to the normal line to the surface of the sample W is referred to as “oblique incidence illumination”. On the other hand, when the reflection mirror A7 is removed from the optical path, the illumination light rays emitted from polarization control unit A5 is perpendicularly incident on the sample W via the reflection mirror A9, a polarization beam splitter B′3, a polarization control unit B′2, a reflection mirror B′1, and a detection optical system B3. In this specification, making illumination light rays incident perpendicularly to the surface of the sample W is referred to as “vertical illumination”.

FIGS. 5 and 6 are schematic diagrams illustrating positional relationships between the optical axis of illumination light rays obliquely guided to the surface of the sample W by the illumination optical system A and an illumination intensity distribution shape. FIG. 5 schematically illustrates a cross section of the sample W taken at an incident plane of illumination light rays incident on the sample W. FIG. 6 schematically represents a cross section of the sample W taken along a plane that is perpendicular to the incident plane of illumination light rays that enters the sample W and includes the normal line to the surface of sample W. The incident plane is a plane that includes an optical axis OA of the illumination light rays that enters the sample W and the normal line to the surface of the sample W. FIGS. 5 and 6 illustrate a part of the illumination optical system A, and for example, the emitted light adjustment unit A3 and the reflection mirrors A7 and A8 are not shown.

As described above, when the reflection mirror A7 is inserted into the optical path, the illumination light rays emitted from the laser light source A1 are condensed by the condensing optical unit A6, reflected by the reflection mirror A8, and obliquely incident on the sample W. In this way, the illumination optical system A is configured to allow illumination light rays to be obliquely incident on the surface of the sample W. This oblique incidence illumination has its light intensity adjusted by the attenuator A2, its light flux diameter adjusted by the beam expander A4, and its polarization adjusted by the polarization control unit A5, thereby making the illumination intensity distribution uniform within the incident plane. Like an illumination intensity distribution (illumination profile) LD1 shown in FIG. 5, the illumination spot formed in the sample W has a Gaussian light intensity distribution in the s2 direction, and the length of a beam width 11 defined by 13.5% of the peak is, for example, about 25 μm to 4 mm. When the beam width 11 is long, the throughput of the entire surface inspection improves, but the in-plane resolution of the sample W decreases.

In a plane perpendicular to the incident plane and the sample surface, the illumination spot has a light intensity distribution where the peripheral intensity is weak relative to the center of the optical axis OA, as shown in an illumination intensity distribution (illumination profile) LD2 shown in FIG. 6. This light intensity distribution is, for example, a Gaussian distribution that reflects the intensity distribution of light rays incident on the condensing optical unit A6, or an intensity distribution similar to a Bessel function of the first kind of the first order or a sinc function reflecting the aperture shape of the condensing optical unit A6. In order to reduce the haze generated from the surface of the sample W, the length 12 of the illumination intensity distribution in the plane perpendicular to the incident plane and the sample surface is set to be shorter than the beam width 11 shown in FIG. 5, for example, about 1 μm to 20 μm. The length 12 of this illumination intensity distribution is the length of a region having an illumination intensity of 13.5% or more of the maximum illumination intensity in a plane perpendicular to the incident plane and the sample surface.

Further, the incident angle (the angle of inclination of the incident optical axis with respect to the normal line to the sample surface) of the oblique incidence illumination on the sample W is adjusted to an angle suitable for detecting minute defects by the positions and angles of the reflection mirrors A7 and A8. The angle of the reflection mirror A8 is adjusted by an adjustment mechanism A8a. For example, the larger the incident angle of the illumination light rays on the sample W (the smaller the illumination elevation angle between the sample surface and the incident optical axis), the weaker the scattered light rays (haze) from minute irregularities such as roughness and patterns on the sample surface, which becomes noise compared to the scattered light rays from minute defects on the sample surface. From the viewpoint of suppressing the influence of haze on the detection of minute defects, it is preferable to set the incident angle of the illumination light rays to, for example, 75 degrees or more (elevation angle of 15 degrees or less). On the other hand, in oblique incidence illumination, the smaller the illumination incident angle, the greater the absolute amount of scattered light rays from minute foreign matters. Therefore, from the viewpoint of aiming to increase the amount of scattered light rays from defects, it is preferable to set the incident angle of the illumination light rays to, for example, 60 degrees or more and 75 degrees or less (elevation angle of 15 degrees or more and 30 degrees or less). Vertical illumination, in which the reflection mirror A7 is removed from the optical path of the illumination optical system A and the illumination light rays are incident substantially perpendicularly to the surface of the sample W, is suitable for obtaining scattered light rays from concave defects on the surface of the sample W.

### Detection Optical System

The detection optical system B1 to Bn (n=1, 2 . . . ) is a unit that collects scattered light rays from the sample surface, and is composed of a plurality of optical elements including a condensing lens (objective lens). n in the detection optical system Bn represents the number of detection optical systems, and an example will be described in which the defect inspection apparatus 100 of this embodiment is equipped with 13 sets of detection optical systems (n=13). However, the number of detection optical systems B1 to Bn is not limited to 13, and may be increased or decreased as appropriate. Further, the layout of the detection apertures (described below) of the detection optical systems B1 to Bn can be changed as appropriate.

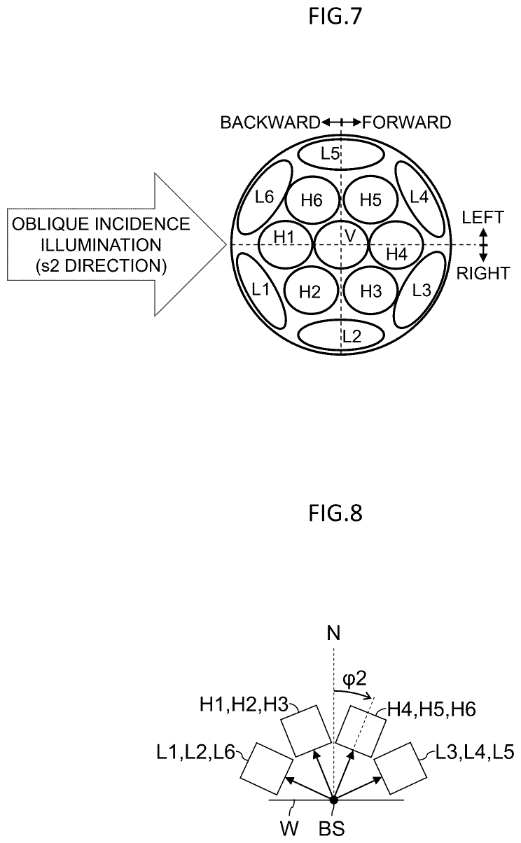

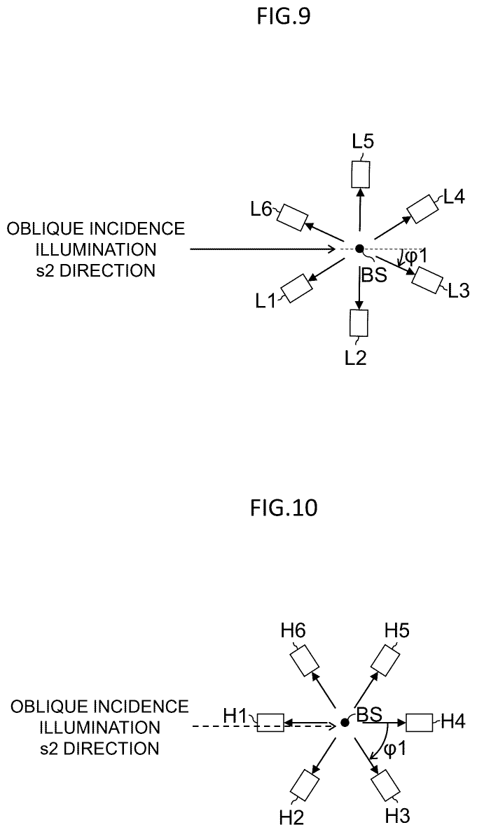

FIG. 7 is a diagram illustrating an area where the detection optical systems B1 to B13 collect scattered light rays when viewed from above, and corresponds to the arrangement of each objective lens of the detection optical systems B1 to B13. FIG. 8 is a diagram schematically illustrating detection zenith angles of low-angle and high-angle optical systems of the detection optical systems B1 to B13. FIG. 9 is a plan view illustrating a detection azimuth angle of the low-angle detection optical system. FIG. 10 is a plan view illustrating a detection azimuth angle of the high-angle detection optical system.

In the following description, based on the incident direction of the oblique incidence illumination on the sample W, a direction (right direction in FIG. 7) in which the incident light travels with respect to the illumination spot BS on the surface of the sample W is the forward, and an opposite direction (left direction in the same figure) is the backward when viewed from above. The lower side of the illumination spot BS in the figure is the right side, and the upper side is the left side. Also, an angle φ2 (FIG. 8) formed by a detection optical axis (center line of the detection aperture) of each detection optical system B1 to B13 with respect to the normal line N (FIG. 8) of the sample W passing through the illumination spot BS is described as a detection zenith angle. In addition, in plan view, an angle φ1 (FIGS. 9 and 10) formed by the detection optical axis (center line of the detection aperture) of each detection optical system B1 to B13 with respect to the incident plane of oblique incidence illumination is described as a detection azimuth angle.

As illustrated in FIGS. 7 to 10, each objective lens (detection apertures L1 to L6, H1 to H6, V) of the detection optical systems B1 to B13 is arranged along a hemispherical surface of the upper half of a sphere (celestial sphere) centered on the illumination spot BS for the sample W. The light rays incident on the detection apertures L1 to L6, H1 to H6, and V are respectively collected by the corresponding detection optical systems B1 to B13.

The detection aperture V overlaps (intersects the normal line N) the zenith and is located directly above the illumination spot BS formed on the surface of the sample W (detection zenith angle φ2=0°).

The detection apertures L1 to L6 are opened so as to equally divide an annular region surrounding 360 degrees around the illumination spot BS at a low angle. The detection zenith angle φ2 of these low-angle detection apertures L1 to L6 is 45° or more. The detection apertures L1 to L6 are arranged in the order of detection apertures L1, L2, L3, L4, L5, and L6 in a counterclockwise direction from the incident direction of the oblique incidence illumination in plan view. Further, the detection apertures L1 to L6 are laid out to avoid the incident optical path of oblique incidence illumination and a specular reflection optical path. The detection apertures L1 to L3 are arranged on the right side of the illumination spot BS, the detection aperture L1 is located on the right backward of the illumination spot BS, the detection aperture L2 is located on the right side of the illumination spot BS, and the detection aperture L3 is located on the right forward of the illumination spot BS. The detection apertures L4 to L6 are arranged on the left side with respect to the illumination spot BS, the detection aperture L4 is located on the left forward of the illumination spot BS, the detection aperture L5 is located on the left side of the illumination spot BS, and the detection aperture L6 is located on the left backward of the illumination spot BS. For example, the detection azimuth angle φ1 of the forward detection aperture L3 is set to 0° to 60°, the detection azimuth angle φ1 of the side detection aperture L2 is set to 60° to 120°, and the detection azimuth angle φ1 of the backward detection aperture L1 is set to 120° to 180°. The arrangement of the detection apertures L4, L5, and L6 is symmetrical with the detection apertures L3, L2, and L1 with respect to the incident plane of oblique incidence illumination.

The detection apertures H1 to H6 are opened so as to equally divide an annular region surrounding 360 degrees around the illumination spot BS at a high angle (between the detection apertures L1 to L6 and the detection aperture V). The detection zenith angle φ2 of these high-angle detection apertures H1 to H6 is 45° or less. The detection apertures H1 to H6 are arranged in the order of detection apertures H1, H2, H3, H4, H5, and H6 in a counterclockwise direction from the incident direction of the oblique incidence illumination in plan view. Of the detection apertures H1 to H6, the detection apertures H1 and H4 are laid out at positions intersecting the incident plane, with the detection aperture H1 being located on the backward of the illumination spot BS, and the detection aperture H4 being located on the forward of the illumination spot BS. The detection apertures H2 and H3 are arranged on the right side of the illumination spot BS, the detection aperture H2 is located on the right backward of the illumination spot BS, and the detection aperture H3 is located on the right forward of the illumination spot BS. The detection apertures H5 and H6 are arranged on the left side with respect to the illumination spot BS, the detection aperture H5 is located on the left forward of the illumination spot BS, and the detection aperture H6 is located on the left backward of the illumination spot BS. In this example, the detection azimuth angle φ1 of the high-angle detection apertures H1 to H6 is shifted by 30 degrees from the low-angle detection apertures L1 to L6.

Scattered light rays scattered in various directions from the illumination spot BS enter the detection apertures L1 to L6, H1 to H6, and V, and are respectively collected by the detection optical systems B1 to B13, and the light rays are guided to corresponding sensors C1 to C13, C1′ to C13′.

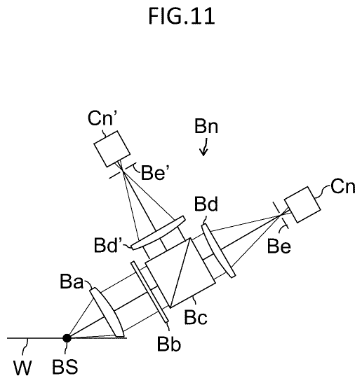

FIG. 11 is a schematic diagram illustrating an example of a configuration diagram of a detection optical system. In the defect inspection apparatus of this embodiment, each detection optical system B1 to B13 (or a part of the detection optical system) is configured like the detection optical system Bn illustrated in FIG. 11, and a polarization direction of the scattered light rays to be transmitted can be controlled by a polarizing plate Bb. In particular, the detection optical system Bn includes an objective lens (condensing lens) Ba, a polarizing plate Bb, a polarization beam splitter Bc, imaging lenses (tube lenses) Bd and Bd′, and field stops Be and Be′.

The scattered light rays incident on the detection optical system Bn from the sample W is collected and collimated by the objective lens Ba, and its polarization direction is controlled by the polarizing plate Bb. The polarizing plate Bb is a half-wavelength plate and can be rotated by a drive mechanism (not illustrated). By controlling the drive mechanism using the control device E1 and adjusting the rotation angle of the polarizing plate Bb, the polarization direction of the scattered light rays incident on the sensor is controlled.

The optical path of the scattered light rays of which the polarization is controlled by the polarizing plate Bb is branched by the polarization beam splitter Bc according to the polarization direction, and then enters the imaging lenses Bd and Bd′. The combination of the polarizing plate Bb and the polarization beam splitter Bc cuts linearly polarized light components in any direction. When cutting arbitrary polarized light components including elliptically polarized light rays, a polarizing plate Bb is composed of a quarter-wavelength plate and a half-wavelength plate that can be rotated independently of each other.

The scattered illumination light rays that have passed through the imaging lens Bd and are collected are photoelectrically converted by the sensor Cn via the field stop Be, and its detection signal is input to the signal processing device D. The scattered illumination light rays that pass through the imaging lens Bd′ and are collected are photoelectrically converted by the sensor Cn′ via the field stop Be′, and its detection signal is input to the signal processing device D. The field stops Be and Be′ are installed so that their centers align with the optical axis of the detection optical system Bn. The field stops Be and Be′ cut off light rays generated from a position other than an inspection target position, such as light rays generated from a position away from the center of the illumination spot BS of the sample W, and stray light rays generated inside the detection optical system Bn. This has the effect of suppressing noise that interferes with defect detection.

According to the above configuration, two mutually orthogonal polarized light components of the scattered light rays can be detected simultaneously, which is effective when detecting a plurality of types of defects with different polarization characteristics of the scattered light rays.

In order to efficiently detect the scattered light rays with the sensors Cn and Cn′, it is preferable to use the objective lens Ba with a numerical aperture (NA) of 0.3 or more. In addition, in configuring the objective lens Ba with a plurality of lenses arranged closely, in order to reduce the loss of detected light amount due to gaps between lenses, as in the example of FIG. 11, an outer periphery of the objective lens Ba may be cut out so as not to interfere with the sample W or other objective lenses.

### Sensor

The sensors C1 to C13 and C1′ to C13′ are sensors that convert scattered light rays collected by the corresponding detection optical system into electrical signals and output detection signals. The sensors C1 (C1′), C2 (C2′), C3 (C3′) . . . correspond to the detection optical systems B1, B2, B3 . . . . For these sensors C1 to C13′, single-pixel point sensors such as photomultiplier tubes and silicon photomultipliers (SiPMs), which photoelectrically convert weak signals with high gain, can be used. In addition, sensors in which a plurality of pixels are arranged in one or two dimensions, such as a CCD sensor, a CMOS sensor, or a position sensing detector (PSD), may be used as the sensors C1 to C13′. Detection signals output from the sensors C1 to C13′ are input to the signal processing device D at any time.

### Control Device

The control device E1 is a computer that centrally controls the defect inspection apparatus 100, and includes ROM, RAM, and other storage devices as well as processing devices (arithmetic control devices) such as a CPU, GPU, and FPGA. The control device E1 is connected to the input device E2, the monitor E3, and the signal processing device D by wire or wirelessly. The input device E2 is a device through which a user inputs inspection condition settings and the like to the control device E1, and various input devices such as a keyboard, mouse, touch panel, and the like can be employed as appropriate. The control device E1 receives the outputs (rθ coordinates on the sample of the illumination spot BS) of encoders of the rotation stage and the translation stage, inspection conditions input by an operator via the input device E2, and the like. Inspection conditions include the type, size, shape, material, illumination conditions, detection conditions, and the like of the sample W, as well as sensitivity settings for each sensor C1 to C13′, gain values and threshold values used for defect determination.

Further, according to the inspection conditions, the control device E1 outputs a command signal for commanding the operation of the stage ST, the illumination optical system A, and the like, or outputs coordinate data of the illumination spot BS in synchronization with the defect detection signal to the signal processing device D. The control device E1 also displays and outputs an inspection condition setting screen and sample inspection data (inspection images and the like) to the monitor E3. The inspection data can display not only the final inspection results obtained by integrating signals of the sensors C1 to C13′ but also the individual inspection results of these sensors C1 to C13′.

Further, as illustrated in FIG. 1, a Review Scanning Electron Microscope (SEM), which is an electron microscope for defect inspection, may be connected to the control device E1. In this case, it is also possible to receive defect inspection result data from the Review SEM by the control device E1 and send it to the signal processing device D.

This control device E1 can be composed of a single computer that forms a unit with an apparatus main body (stage, illumination optical system, detection optical system, sensor, and the like) of the defect inspection apparatus 100, but the control device E1 can also be composed of a plurality of computers connected through a network. For example, a configuration may be adopted in which inspection conditions are input to a computer connected via a network, and the apparatus main body and the signal processing device D are controlled by a computer attached to the apparatus main body.

### Signal Processing Device

The signal processing device D is a computer that processes detection signals input from the sensors C1 to C13′. The signal processing device D, like the control device E1, includes a memory D1 (FIG. 20) including at least one of RAM, ROM, HDD, SSD, and other storage devices, as well as processing devices such as a CPU, GPU, and FPGA. This signal processing device D can be composed of a single computer that forms a unit with an apparatus main body (stage, illumination optical system, detection optical system, sensor, and the like) of the defect inspection apparatus 100, but the signal processing device D can also be composed of a plurality of computers connected via a network. For example, the computer attached to the apparatus main body can acquire defect detection signals from the apparatus main body, process the detected data as necessary and send the processed data to the server, and the server can execute processing such as defect detection and classification.

### Example of Related Art

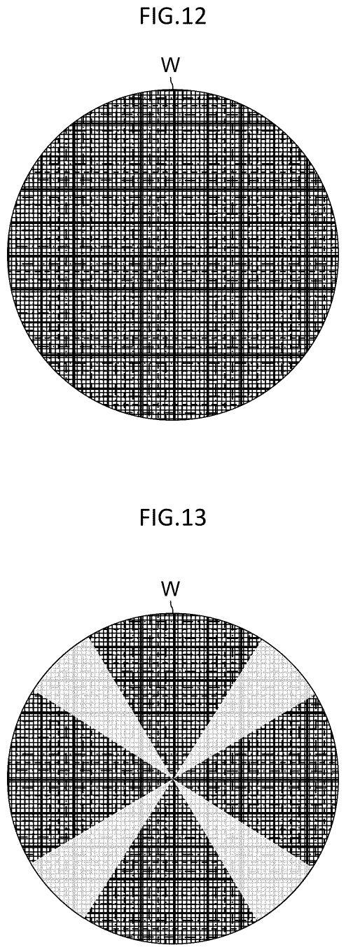

FIGS. 12 and 13 are schematic diagrams illustrating examples of detection maps when a patterned wafer is measured defect inspection apparatus with the rotational scanning method. In the example of FIG. 12, it can be seen that only minute structures such as patterns normally formed on the surface of the sample W, such as boundaries between adjacent dies and patterns within dies, are detected. In the other example illustrated in FIG. 13, it can be seen that light rays generated in a region radiating from the center of the sample W is strongly detected.

When illumination light rays are incident on the pattern formed on the surface of the sample W, strong light rays are emitted at edges of the pattern. Sometimes the light rays from the pattern are so strong that the sensor becomes saturated. Therefore, it is usual that inspection cannot be performed as is. It is also possible to perform inspection by lowering the output of the laser light source A1 to a level that does not saturate the sensor. However, in that case, the sensitivity will be greatly reduced, which is not preferable.

The pattern formed on the surface of the sample W may include many patterns with line widths smaller than the size of the illumination spot BS. Further, the surface of the sample W includes not only a pattern but also surface roughness as minute irregularities. When illumination light rays are incident on such extremely fine patterns or roughness on the surface of the sample W, scattered light rays are generated from the minute irregularities on a substrate surface. However, unlike the roughness of the substrate surface, a pattern has a shape characteristic in which its edges mainly extend in vertical and horizontal directions (x and y directions) in the xy orthogonal coordinate system of the sample W, and the layout is characterized by being arranged in the vertical and horizontal directions. The strength of the signal intensity appearing radially as shown in FIG. 13 is caused by the change in the emission direction and intensity of the diffracted light rays generated by such a pattern as the sample W rotates. In other words, the coordinates where the diffracted light rays are strongly generated and the generated diffracted light rays are easily detected by the detection optical systems B1 to B13 are detected mixed with the coordinates where the defect exists.

Therefore, when illumination light rays are applied to the surface of the sample W on which many patterns (fine structures) are formed, as illustrated in FIGS. 12 and 13, a large amount of scattered light rays and diffracted light rays from the pattern are detected, and these undesired light rays become noise and obstruct defect detection. Therefore, in order to accurately inspect defects in the sample W, it is desirable to suppress the detection of scattered light rays and diffracted light rays from these patterns, or to suppress the influence of detection signals of scattered light rays and diffracted light rays from patterns on defect determination.

### Change in Emission Direction of Diffracted Light Rays Depending on Sample Angle

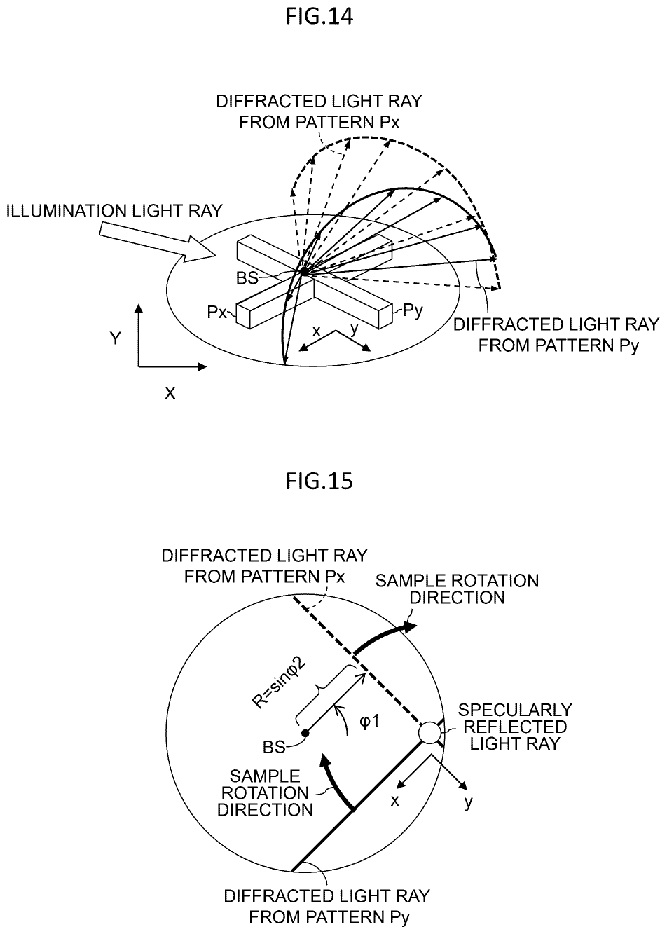

FIG. 14 is a schematic diagram illustrating a relationship between the emission direction of diffracted light rays generated by the pattern and the angle of the sample. FIG. 14 shows a linear (rectangular) pattern Px extending in the x direction and a linear (rectangular) pattern Py extending in the y direction as typical examples of patterns. The diffracted light rays generated from the edges of the patterns Px and Py are emitted in a generatrix direction of a cone with the illumination spot BS as the apex, as illustrated in FIG. 14. The emission direction of the diffracted light rays generated by the pattern Px and the emission direction of the diffracted light rays generated by the pattern Py are different from each other. Further, when the orientation of the patterns Px and Py with respect to the illumination light rays changes with the rotation of the sample W, the emission direction of the diffracted light rays also changes accordingly.

Incident points of the diffracted light rays illustrated in FIG. 14 for the detection apertures L1 to L6, H1 to H6, and V of each detection optical system B1 to B13 are distributed on an intersection line between a spherical surface (a hemispherical surface on which the detection aperture L1 and the like are arranged) centered on the illumination spot BS and a conical surface related to the traveling direction of the diffracted light rays. FIG. 15 shows a diagram of this intersection line projected onto the xy plane (horizontal plane passing through the illumination spot BS). The distribution of the incident points of the diffracted light rays illustrated in FIG. 15 becomes a straight line at a distance R (=sin φ2) from the illumination spot BS using the detection azimuth angle φ1 and the detection zenith angle φ2 that define the emission direction of the diffracted light rays from the patterns Px and Py, with the radius of the hemisphere as a unit distance.

In the xy coordinate system of the sample W, the distribution of the incident points of the diffracted light rays is equal to a shape obtained by Fourier transforming the linear shape of the light source (pattern edge in this example) due to the fine structure overlapping the illumination spot BS. The origin of the frequency of this Fourier transform is a point where the incident point of the specularly reflected light rays of the illumination light rays on the hemispherical surface is projected onto the xy plane. Since the pattern Px is uniform in the x direction and delta function shaped in the y direction on the xy plane, the distribution of the incident points of the diffracted light rays is delta function shaped in the x direction and uniform in the y direction. That is, the distribution of the incident points of the diffracted light rays generated at the edges of the pattern Px becomes a linear distribution extending in the y direction passing through the incident point (projection point) of the specularly reflected light rays on the xy plane. In addition, when the illumination spot BS straddles a plurality of patterns Px arranged periodically in the y direction, the distribution of the diffracted light rays in the y direction becomes a periodic (intermittent) distribution obtained by Fourier transform, and is included in the linear diffracted light distribution illustrated in FIG. 15. The distribution of the incident points of the diffracted light rays generated at the edges of the pattern Py is also similar, and on the xy plane, the incident point (projection point) of the specularly reflected light rays intersects (in this example, perpendicularly intersects with) the distribution straight line of the diffracted light rays of the pattern Px, resulting in a linear distribution extending in the x direction.

During inspection, the orientation of the patterns Px and Py overlapping the illumination spot BS changes as the sample W rotates, so the distribution of the incident points of the diffracted light rays obtained by Fourier transforming the edge shapes of the patterns Px and Py also rotates around the incident point of the specularly reflected light ray in accordance with the rotation of the sample W. Therefore, the distribution of diffracted light rays is also rotated by the same angle as the rotation angle of the sample W.

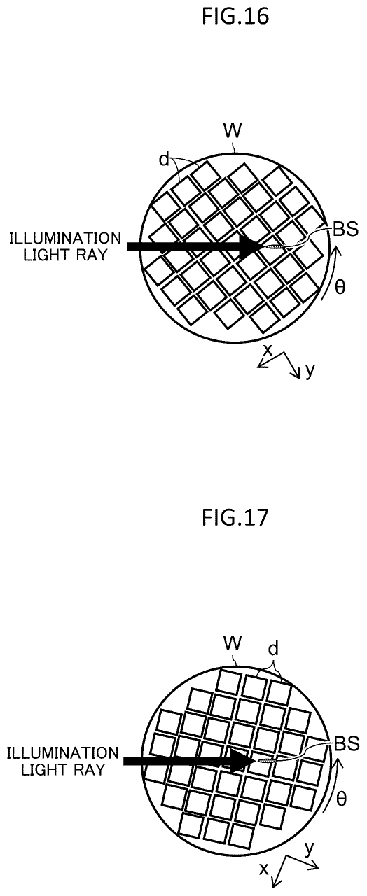

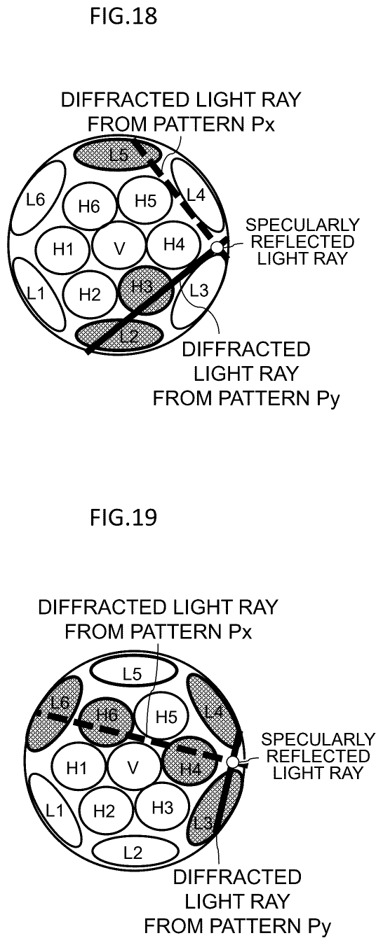

FIGS. 16 and 17 are schematic diagrams illustrating changes in the rotation angle of a sample with respect to an illumination light ray, and FIGS. 18 and 19 are schematic diagrams illustrating changes in the emission direction of diffracted light rays depending on the rotation angle of the sample. FIG. 18 illustrates the emission direction of the diffracted light rays generated in the sample W of FIG. 16, and FIG. 19 illustrates the emission direction of the diffracted light rays generated in the sample W of FIG. 17.

In the sample W, a large number of dies d each having a pattern of the same design are arranged in the x and y directions (in a matrix).

When the orientation of the sample W changes with rotational scanning, the orientation of the sample W with respect to the illumination light ray changes as illustrated in FIGS. 16 and 17. When the orientation of the sample W with respect to the illumination light ray is different, even when the pattern into which the illumination light ray enters has the same shape, the way the diffracted light ray generated by the pattern comes out changes, and the detection aperture into which the diffracted light ray enters changes as illustrated in FIGS. 18 and 19. As a result, the strength of the output signal of each sensor C1 to C13′ changes, and it is difficult to compare the signals even between dies of the same design and distinguish and exclude the detection signal of a diffracted light ray from the detection signal of a defect.

### Calculating Filter Data

In this embodiment, based on the position (coordinates) on the surface of the sample W, the detection signal of the pattern is removed (first filter), and the detection signal of the diffracted light ray generated by the pattern is removed (second filter) based on the θ coordinate of the sample W in the circular coordinate system. The first filter and the second filter remove the detection signal caused by the normally formed pattern, and extract the detection signal of the inspection target part. The defect in the sample W is detected by processing the detection signals extracted by the first filter and the second filter by the signal processing device D.

### First Filter

In this embodiment, the first filter is program processing executed by the signal processing device D, and based on pattern mask data corresponding to the layout of the pattern on the surface of the sample W, the detection signal at the coordinates where the pattern exists is removed using a predetermined algorithm. The pattern mask data used in this process is one type of filter data. The pattern mask data is a data set of coordinates to be removed as a pattern detection signal.

In this embodiment, the pattern mask data is automatically created based on the design data (pattern coordinates, wiring width, and the like) of the sample W, and is stored, for example, in the memory of the signal processing device D or control device E1, or in the storage device DB. As described above, the signal processing device D and the control device E1 can be composed of a plurality of computers connected via a network, so the pattern mask data may be stored in a data server that constitutes the signal processing device D or the control device E1. In other words, it is also possible to adopt a configuration in which pattern mask data is transmitted to a computer connected via a network and stored.

Further, the pattern mask data can be configured to be calculated by the signal processing device D or the control device E1. In addition, the pattern mask data can be calculated in advance on a computer different from the signal processing device D and the control device E1, and stored in the memory of the signal processing device D or the control device E1, or in the storage device DB. In addition, the pattern mask data may be one that faithfully imitates the design layout of the pattern, but it is preferable that patterns are divided into classes based on wiring width, pitch of adjacent wiring, and the like, and generated based on pattern data of classes that can be resolved with the set resolution of the defect inspection apparatus 100. When an observation image of a pattern can be acquired using an electron microscope such as the above-described DR-SEM, a configuration may be adopted in which pattern mask data is generated based on an observation image of a pattern using an electron microscope.

FIG. 20 is a schematic diagram illustrating an example of pattern mask data as an image. The figure shows an example of simple grid-like (mesh-like) pattern mask data PM, but the pattern mask data PM can also be a high-definition copy of the pattern, die boundaries, or the like based on the pattern design data. In the signal processing device D, by removing data at coordinates overlapping this pattern mask data PM from the defect detection data, a scattered light ray (that is, a pattern detection signal) generated on a flat surface of a normally formed pattern is removed. The pattern detection signal can be removed before or after the defect determination process, but from the viewpoint of data processing efficiency, it is preferable to remove the pattern detection signal before the defect determination process.

The effectiveness of the pattern mask data PM can be verified prior to inspection of the sample W. For example, regarding the sample W or a sample of the same type or equivalent as the sample W that has been inspected for defects, a good sample with the number of defects below a tolerance value, and a bad sample with the number of defects exceeding the tolerance value are prepared. The sample of the same type as the sample W is a sample that has the same surface structure (pattern design, or the like) as the sample W on the entire surface. The sample equivalent as the sample W is a sample that partially differs in surface structure from the sample W, but includes a predetermined proportion or more of parts having the same intra-sample coordinates and the same surface structure. Using the created pattern mask data PM, the good samples and the bad samples are subjected to post-scanning, and then when a difference between the difference between the two measurement results and the difference in the number of defects between the good sample and the bad sample is equal to or less than a set value, it can be determined that the pattern mask data PM is functioning effectively. When the effectiveness of the pattern mask data PM cannot be confirmed, the pitch, line width, and shape of the pattern mask are changed while looking at the difference in measurement results, and then the pattern mask can be adjusted so that the difference between the difference between the measurement results and the difference in the number of defects between the good samples and the bad samples is equal to or less than the set value.

### Second Filter

Further, in this embodiment, the second filter is also a program processing executed by the signal processing device D, and based on the haze data of the sample W, the detection signals of the sensors C1 to C13′ are removed according to the θ coordinate of the sample W, and the detection signal of the diffracted light ray is removed or reduced using a predetermined algorithm. The haze data is data on the intensity of a detection signal obtained by scanning a normal region on the surface of the sample W, and may be displayed in a map form as a distribution within the surface of the sample. This haze data is also one of the filter data. The surface shape of the sample W has a feature that finer patterns than the illumination spot BS are lined up in the x and y directions, so the haze data can be simulated based on the rotation angle of the sample W with respect to the illumination light ray and the detection azimuth angle φ1 of the detection aperture of each detection optical system B1 to B13. When reducing the detection signal of a diffracted light ray, algorithms such as reducing the detection signal by the intensity of the detection signal of the diffracted light ray generated in a normal pattern, or reducing the detection signal by multiplying by a gain set based on the intensity of the detection signal of the diffracted light ray can be applied. Like the pattern mask data, the haze data is also stored, for example, in the memory of the signal processing device D or control device E1, or in the storage device DB. This haze data can also be calculated by the signal processing device D or the control device E1, and further this haze data can also be calculated in advance on a computer different from the signal processing device D and the control device E1 and stored in the memory of the signal processing device D or control device E1, or in the storage device DB.

In addition, since the emission direction of the diffracted light ray is correlated with the θ coordinate, a frequency filter that removes or reduces the detection signal of the diffracted light ray at a set period according to the rotation speed of the sample W (sample stand ST1) during the inspection of the sample W can also be applied as the second filter.

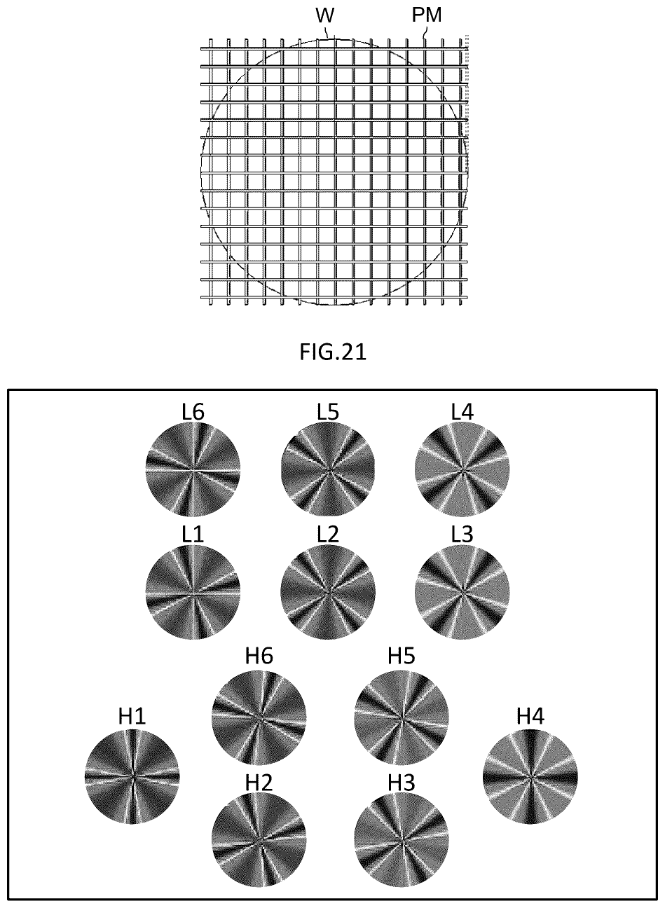

FIG. 21 is a diagram illustrating, as an example of haze data for each sensor C1 to C13′, an example of haze data based on the haze incident on the detection apertures L1 to L6 and H1 to H6 of each detection optical system. As shown in the figure, the strength of haze varies depending on the coordinates of the sample W due to the influence of diffraction. As described above, as the sample W rotates, the emission direction of the diffracted light ray generated by the pattern rotates, which causes a difference in haze data for each detection optical system. In the signal processing device D, from among the detection signals of the sensors, those determined to be detection signals of diffracted light rays based on the corresponding haze data are removed. For example, when it is determined based on each haze data that diffracted light ray generated at an arbitrary coordinate P1 of the sample W enters the detection apertures L6 and H6, the detection signals of the light rays incident on the detection apertures L6 and H6 are excluded, and the coordinate P1 is inspected based on the detection signals of the light rays incident on the detection apertures L1 to L5 and H1 to H5.

### Defect Inspection

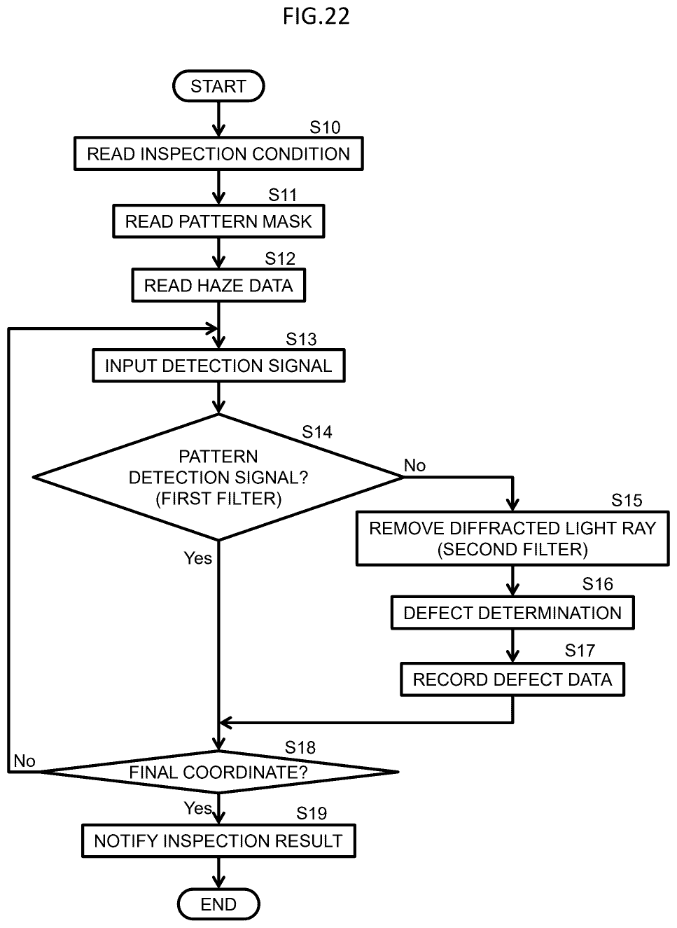

FIG. 22 is a flowchart illustrating a procedure of defect inspection by the signal processing device D.

### Steps S10 to S12

When the defect inspection procedure is started, the signal processing device D reads the inspection conditions from the control device E1 (step S10), and then the pattern mask data and haze data are read from the memory of the control device E1 or signal processing device D, or the storage device DB (steps S11 and S12).

### Steps S13 and S14

Then, when the apparatus main body is controlled by the control device E1 and detection signals are input from the sensors C1 to C13′ (step S13), the signal processing device D executes the first filter processing based on the pattern mask data and the coordinate data from the control device E1 (step S14). In this first filter processing, when the signal processing device D determines that the detection signals from the sensors C1 to C13′ are signals for coordinates other than the pattern, the procedure moves to step S15 to continue defect inspection processing for the coordinates. On the other hand, when it is determined that the detection signals from the sensors C1 to C13′ are signals of having detected a pattern, no inspection is performed based on these signals, and the procedure moves to step S18.

### Step S15

Moving the procedure to step S15, the signal processing device D executes the second filter processing based on the haze data and the coordinate data from the control device E1. In this second filter processing, the signal processing device D removes a signal (a signal containing a component of a diffracted light ray) of detecting diffracted light rays from among the detection signals of the sensors C1 to C13′ that have undergone the first filter processing, and only detection signals other than the diffracted light rays (signals that do not contain components of diffracted light rays) are extracted. In the second filter processing, the signal (signal containing a component of a diffracted light ray) of detecting the diffracted light ray may be reduced, and a signal in which the component of the diffracted light ray is reduced may be extracted together with a detection signal (a signal that does not contain the component of the diffracted light ray) other than the diffracted light ray.

### Steps S16 and S17

Next, the signal processing device D determines whether these detection signals are a defect detection signal based on the detection signals extracted by the processing of the first filter and the second filter (step S16), and the determination result is recorded in the memory (step S17). For example, each detection signal can be integrated and compared with a threshold value, and when the integrated signal exceeds a threshold value, it can be determined that the integrated signal is a defect detection signal. Also, each detection signal is compared with each threshold value set according to the sample coordinates, and when there are more than the set number of detection signals exceeding the threshold value, it is also possible to determine that these detection signals are defect detection signals.

### Steps S18 and S19

When the procedure moves from step S14 or S17 to step S18, the signal processing device D determines whether the detection signal being processed in the current cycle is a signal at an end point coordinate of the scanning trajectory of the sample W. When the progress of the inspection has not reached a final coordinate, the signal processing device D returns the procedure to step S13. When the processing of the detection signal of the final coordinate is completed, the signal processing device D moves the procedure to step S19, notifies the control device E1 of the inspection result, and ends the flow of FIG. 22. The inspection results obtained by the signal processing device D are displayed on the monitor E3 by the control device E1. In this example, an example is described in which the inspection results are displayed on the monitor E3 after the inspection of the sample W is completed, but a configuration may also be adopted in which inspection data is sequentially transmitted from the signal processing device D according to the progress of the inspection, and the display of the inspection results is updated with the progress of the inspection.

### Effect

(1) According to the present embodiment, by providing the plurality of sensors C1 to C13′ with different detection azimuth angles φ1 and detection zenith angles φ2, defects in the sample W can be inspected by following the rotation of the sample W. As described above, the detection signal of the pattern can be removed or reduced by the first filter, and the influence of the diffracted light ray generated by the pattern can be removed or reduced by the second filter. By suppressing the influence of scattered light rays and diffracted light rays generated by the pattern, in the same way as substrates (bare wafers, or the like) on which fine structures such as patterns are not formed, the sample W on which fine structures such as patterns are formed can be inspected with high accuracy using the rotational scanning method. The sample W, such as a patterned wafer, which is previously inspected using the XY scanning method due to the fine structures formed on the surface, can now be inspected using the rotational scanning method, making it possible to significantly improve throughput. For example, compared to the XY scanning method, the inspection time per sample can be reduced to less than half, and thus the inspection cost per sample can also be reduced.
(2) Focusing on the structural characteristics of the sample W, which has patterns finer than illumination spot BS arranged more densely in the x and y directions, the emission direction of the diffracted light ray generated by the pattern is calculated according to the rotation angle of the sample W, and haze data can be generated for each sensor C1 to C13′. Thereby, the detection signal of the diffracted light ray can be removed or reduced for each sensor C1 to C13′ according to the coordinates on the surface of the sample W. In other words, while suppressing the influence of diffracted light rays on defect inspection with the second filter, detection signals with no or little influence of diffracted light rays can be effectively utilized for defect inspection. This point also contributes to ensuring high inspection accuracy.
(3) By generating pattern mask data based on the pattern layout of the sample W and filtering the detection signal of the coordinates where the pattern is estimated to exist on the surface of the sample W, pattern detection signals can be removed efficiently. By removing the pattern detection signal, the load on the signal processing device D regarding data processing and storage can be reduced. In particular, by generating pattern mask data based on pattern design data as in this embodiment, the reliability of the pattern mask data can be increased and pattern detection signals can be removed with high precision.

### Second Embodiment

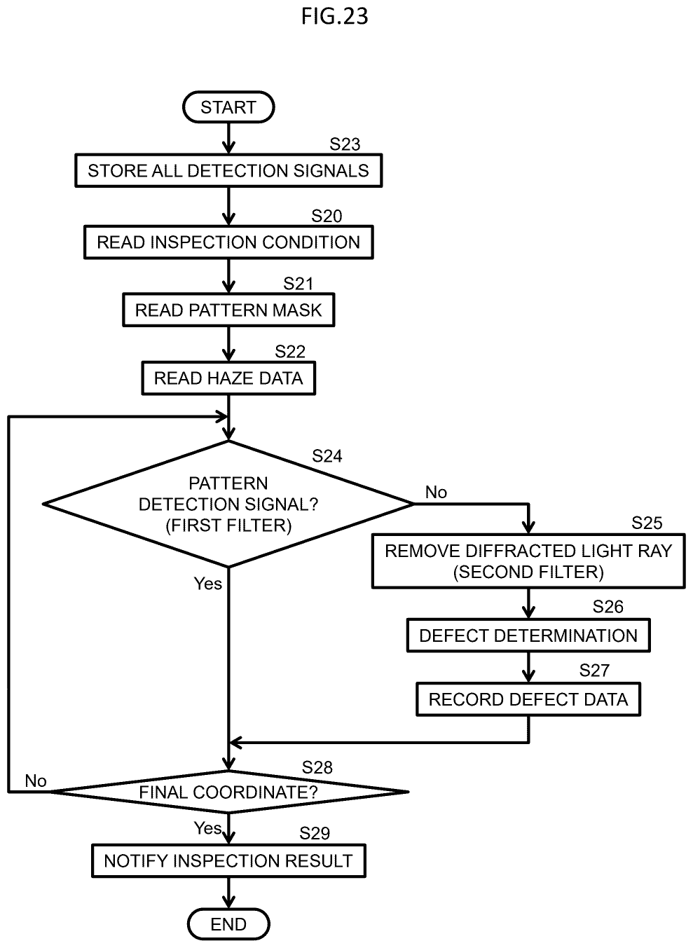

FIG. 23 is a flowchart illustrating a defect inspection procedure of a defect inspection apparatus according to a second embodiment of the present invention. This figure corresponds to FIG. 22 of the first embodiment.

In the first embodiment, an example is described in which detection signals input from the sensors C1 to C13′ are sequentially processed, but in this embodiment, all the detection signals acquired after scanning the entire surface of the sample W are temporarily stored in a memory, and the stored data is post-processed to perform defect inspection. In other respects, this embodiment is similar to the first embodiment.

In particular, the signal processing device D first associates the detection signals input from the sensors C1 to C13′ with the coordinates while scanning the sample W after the start of the inspection, and sequentially stores the associated signals and coordinates in the memory of the signal processing device D or the control device E1, or in the storage device DB, and then accumulates data for the entire surface of the sample W (step S23).

After accumulating the data of the entire surface, the signal processing device D reads the inspection conditions from the control device E1 (step S20), and reads the pattern mask data and haze data from the memory of the signal processing device D or the control device E1, or the storage device DB (steps S21 and S22). Next, the data of each coordinate is processed in a predetermined order (for example, along the scanning trajectory), and when all the data has been processed, the inspection result is notified to the control device E1, and the procedure of FIG. 23 is completed (steps S24 to S29). The processing in steps S20 to S22 and S24 to S29 also corresponds to the processing in steps S10 to S12 and S14 to S19 in the first embodiment in content and order.

Also in this embodiment, the similar effects as in the first embodiment can be obtained. In addition, in the case of this embodiment, since all detection signals are stored and post-processed, the small load on arithmetic processing is also advantageous, unlike processing that is executed in real time following scanning. Therefore, for example, by setting a low threshold value for extracting defect candidate signals, a large amount of detection signals including noise can be temporarily stored and defect inspection can be performed on all of these detection signals, which can improve defect detection accuracy.

### Third Embodiment

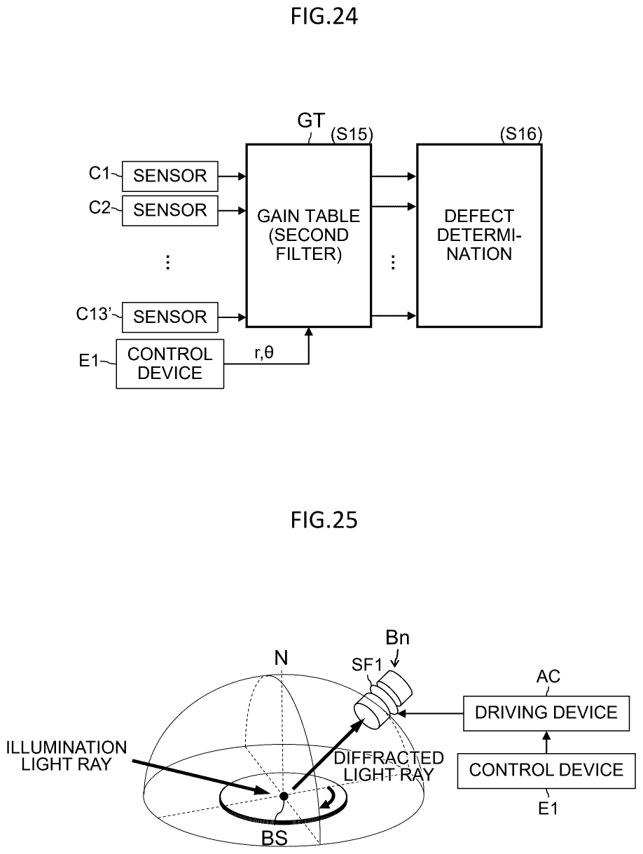

FIG. 24 is a functional block diagram of the second filter of the defect inspection apparatus according to a third embodiment of the present invention.

This embodiment differs from the first embodiment in the algorithm of the second filter as program processing. In the first embodiment, an example is described in which, as the second filter processing, a detection signal estimated to be a detection signal of a diffracted light ray is removed or uniformly reduced. In contrast, in this embodiment, in the second filter processing, the gains of the sensors C1 to C13′ are changed according to the e coordinate or at a set period, and an SN ratio of the sensors C1 to C13′ is changed to remove or reduce the detection signal of the diffracted light ray.

In the second filter processing of this embodiment, the gain is set for each sensor C1 to C13′ according to the intensity of the diffracted light ray based on the haze data. For example, for each sensor C1 to C13′, a gain with a higher attenuation rate is set for a coordinate where the intensity of the detected diffracted light ray is stronger, and a gain with a lower attenuation rate is set for a coordinate where the intensity of the detected diffracted light ray is weaker. Since the intensity of the diffracted light ray has a strong correlation with the θ coordinate among the re coordinates on the surface of the sample W, the gain of each sensor C1 to C13′ is set according to the e coordinate. A gain table GT that summarizes the gains set for each coordinate for each sensor C1 to C13′ in this way is stored in the memory of the signal processing device D or the control device E1, or in the storage device DB.

In this embodiment, during defect inspection, in the process of step S15 (FIG. 22), the signal processing device D removes or attenuates the detection signal affected by the diffracted light ray by multiplying by a gain associated with the inspection coordinate based on the read gain table GT. The individual gains applied to the detection signals of each sensor C1 to C13′ dynamically change depending on the θ coordinate (as the sample W rotates). As a result, for each sensor C1 to C13′, the value of a detection signal that is estimated to have a larger proportion of the diffracted light components decreases at a greater rate, and for a detection signal in which the proportion of the diffracted light components is estimated to be small (or non-existent), a reduction rate becomes small (or does not decrease). Based on the detection signal processed by the second filter, the signal processing device D executes defect determination (step S16 in FIG. 22).

In other respects, this embodiment is similar to the first embodiment. The algorithm of the second filter in this embodiment is also applicable to the second filter (processing in step S25 in FIG. 23) in the second embodiment.

Also in this embodiment, the similar effects as in the first embodiment or the second embodiment can be obtained. In addition, since the individual gains applied to the detection signals of each sensor C1 to C13′ dynamically change according to the θ coordinate, the diffracted light component that occupies the detection signal is appropriately removed for each θ coordinate, and improvement in the accuracy of defect inspection is expected.

### Fourth Embodiment

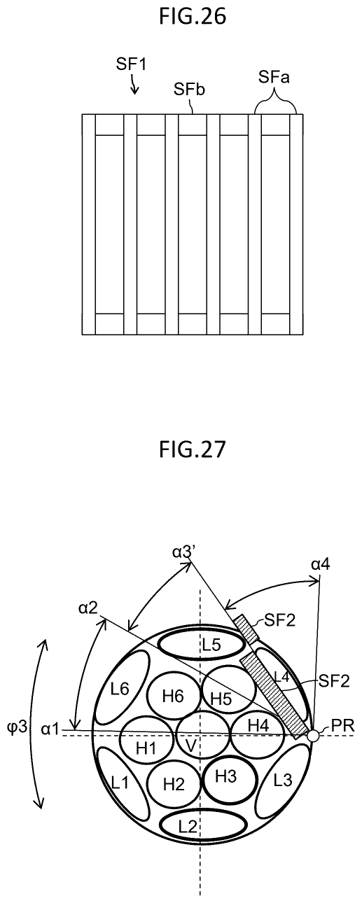

FIG. 25 is a schematic diagram illustrating main parts of a defect inspection apparatus according to a fourth embodiment of the present invention. FIG. 26 is a schematic diagram illustrating a configuration example of a second filter provided in the defect inspection apparatus according to the fourth embodiment of the present invention.

This embodiment differs from the first embodiment in that the second filter is a mechanical filter (spatial filter) rather than program processing. In this embodiment, like the detection optical system Bn illustrated in FIG. 25, a mechanical second filter SF1 is arranged in the Fourier space of each detection optical system B1 to B13 (or some detection optical systems). As illustrated in FIG. 26, these second filters SF1 include, for example, a plurality of rod-shaped light shielding materials SFa arranged in a grid pattern and connected via piezoelectric elements SFb, and the piezoelectric element SFb is driven by an actuator AC to change a pitch of the light shielding material SFa. The actuator AC is driven by a command signal from the control device E1. Further, the second filter SF1 is rotationally driven by the actuator AC. The actuator AC is controlled by the control device E1, and the second filter SF1 is rotationally driven by the actuator AC in synchronization with the sample stand ST1.

Diffracted light rays generated by fine patterns repeatedly formed in the x and y directions and incident on the detection optical system Bn are projected in an intermittent distribution onto the Fourier transform surface of the detection optical system Bn. The pitch of the diffracted light ray that enters the detection optical system Bn in an intermittent distribution changes depending on the degree of density of the repeating pattern. By adjusting the pitch of the light shielding materials of the second filter SF1 according to the pitch of this diffracted light rays and rotating it synchronously with the sample stand ST1, during sample scanning, the diffracted light ray that enters the detection optical system Bn is blocked by the light shielding material (hardware) while changing the emission direction as the sample W rotates.

The pitch of the light shielding material can be determined by simulating the emission direction of the diffracted light ray, for example, based on the pattern layout known from the past inspection data of samples of the same type or equivalent as the sample W and the design data of the sample W. In addition, for example, a configuration can be considered in which a half mirror is arranged on the Fourier transform surface so that the diffracted light rays projected onto the Fourier transform surface can be observed, and the pitch of the light shielding material is adjusted while observing the state of shielding of the diffracted light rays.

This embodiment is similar to the first embodiment except for the above point that the second filter SF1 is applied instead of the second filter which is program processing. Even by physically blocking the diffracted light rays as in this embodiment, the sample W, which is a patterned wafer, can be inspected with high accuracy and high throughput using the defect inspection apparatus 100 with the rotational scanning method.

However, it is also possible to apply the second filter SF1 additionally to the first embodiment, that is, to apply both the second filter as the program processing and the mechanical second filter SF1. In this case, the influence of diffracted light rays can be removed or reduced using both hardware and software, and by suppressing the influence of diffracted light rays that cannot be completely removed or reduced by either method, further improvement in inspection accuracy can be expected. It is of course possible to combine this embodiment with not only the first embodiment but also the second embodiment or the third embodiment.

### Fifth Embodiment

FIG. 27 is a schematic diagram illustrating main parts of a defect inspection apparatus according to a fifth embodiment of the present invention. In the figure, a spherical surface (celestial sphere) on which the detection apertures L1 to L6, H1 to H6, and V of the detection optical systems B1 to B13 are arranged is shown as viewed from the zenith side.

This embodiment differs from the first embodiment in that the second filter is a static shielding structure (such as a light shielding plate). A second filter SF2 in this embodiment is laid out so as to partially block the detection optical path of at least some of the detection optical systems B1 to B13 in order to reduce the number of detection optical systems into which the diffracted light rays generated by the pattern are simultaneously incident. The second filter SF2 can be placed at a position where it interferes with the optical path of the diffracted light ray of the detection optical system, for example, on an object plane side (illumination spot BS side) of the detection aperture. In FIG. 27, for simplicity of description, focus is placed on the detection apertures L4 to L6, and the configuration is illustrated in which the detection apertures L4 and L5 are partially blocked by the second filters SF2 so that diffracted light rays do not enter a plurality among the detection apertures L4 to L6 at the same time.

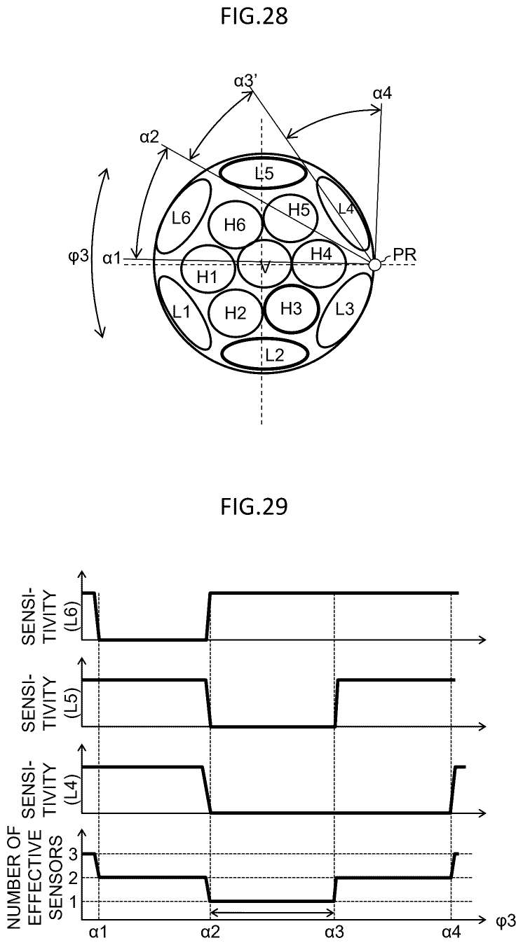

FIG. 28 is a schematic diagram illustrating an incident range of diffracted light rays with respect to the detection apertures L4 to L6 when the second filter SF2 is not provided. In FIG. 28, in a plan view, the incident point of the specularly reflected light rays of the illumination light rays on the celestial sphere is a point PR, and an azimuth angle formed by a line where the incident points of the diffracted light rays are distributed with respect to the incident plane (dotted line extending left and right in FIG. 28) of the illumination light rays with the point PR as the origin is an incident azimuth angle φ3.

As described above in FIG. 15 and the like, in plan view, the points of incidence of the diffracted light rays on the celestial sphere are distributed linearly, the distribution straight line passes through the point PR, and the incident azimuth angle φ3 changes in link with a e coordinate of the sample W. Focusing on the detection apertures L4 to L6, in the example of the same figure, it is assumed that the diffracted light rays emitted can enter the detection aperture L6 in an angular range of α1≤φ3≤α2, the diffracted light can enter the detection aperture L5 in an angular range of α2≤φ3≤3, and the diffracted light can enter the detection aperture L4 in an angular range of α2≤φ3≤α4. In this case, the diffracted light rays emitted in the angular range of α2≤φ3≤α3 can enter the two detection apertures L4 and L5.

FIG. 29 is a graph illustrating a relationship of detection sensitivity of the detection optical system and the number of effective sensors regarding the detection apertures L4 to L6 with respect to the detection azimuth angle for the example of FIG. 28. Here, for ease of description, it is assumed that one sensor corresponds to each of the detection apertures L4 to L6. In this case, there are three sensors in total, but in the angular range of α1≤φ3≤α2, the diffracted light rays enter only the detection aperture L6, and although the sensitivity of the sensor corresponding to the detection aperture L6 decreases, effectiveness for defect inspection is ensured for the two sensors. Similarly, in the angular range of α3≤φ3≤α4, the diffracted light rays enter only the detection aperture L4, and although the sensitivity of the sensor corresponding to the detection aperture L4 decreases, the effectiveness for defect inspection is ensured for the two sensors. However, in the angular range of α2≤φ3≤α3, although the diffracted light rays do not enter the detection aperture L6, the diffracted light rays enter the detection apertures L4 and L5, and the effectiveness of defect inspection is ensured by only one sensor, resulting in a decrease in inspection sensitivity.

Therefore, in this embodiment, as previously shown in FIG. 27, a part of the detection apertures L4 and L5 is blocked by the second filters SF2. Specifically, the detection aperture L5 is blocked in the angular range of α3′≤φ3≤α3, and the detection aperture L4 is blocked in the angular range of α2≤φ3≤α3′, respectively, by the second filters SF2.

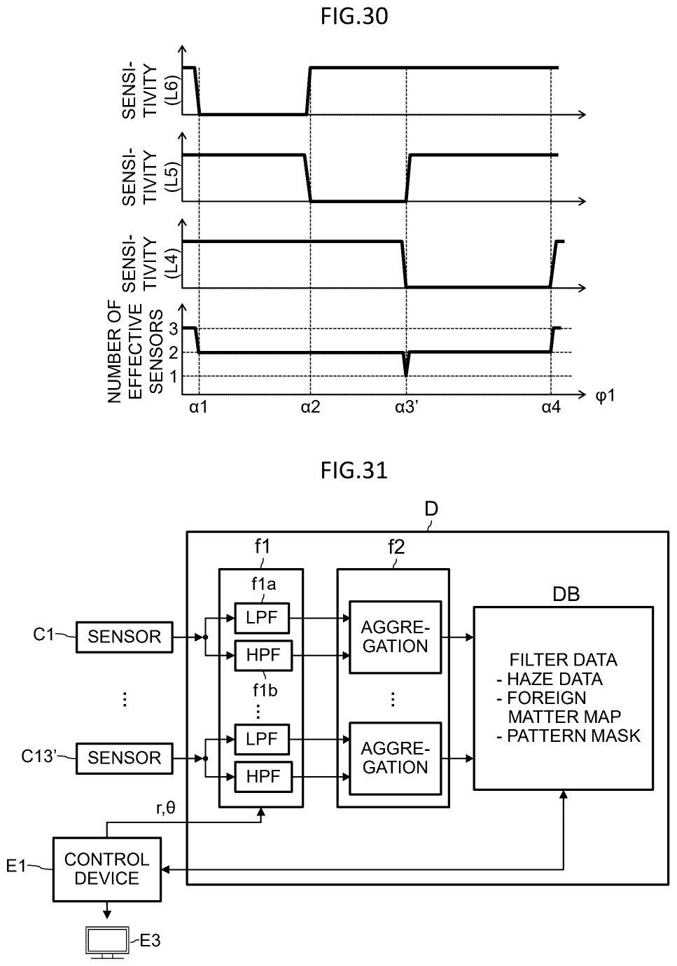

As a result, the diffracted light rays emitted in the angular range of α3′≤φ3≤α3 do not enter the detection apertures L5 and L6, but only enters the detection aperture L4. Further, the diffracted light rays emitted in the angular range of α2≤φ3≤α3′ does not enter the detection apertures L4 and L6, but only enters the detection aperture L5. As a result, as illustrated in FIG. 30, over almost the entire rotation angle of the sample W, a plurality among detection optical systems corresponding to the detection apertures L4 to L6 can be used as effective optical systems that are not affected by diffracted light rays.

This embodiment is the same as the first embodiment, except that the second filter SF2 described above is applied instead of the second filter that is program processing. Also in this embodiment, by suppressing the influence of the diffracted light rays with the second filters SF2, the sample W, which is a patterned wafer, can be inspected with high accuracy and high throughput using the defect inspection apparatus 100 of the rotational scanning method.

In the example of FIG. 28, a configuration may be adopted in which the detection aperture L4 is simply blocked by the second filter SF2 within the angular range of α2≤φ3≤α3. However, in this case, the shielding ratio of the detection aperture L4 becomes large, whereas the example of FIG. 27 is advantageous in that the shielding ratio is allocated to the detection apertures L4 and L5.

Further, the second filter SF2 can be additionally applied to the first embodiment, that is, it is also possible to implement both the second filter as program processing and the second filter SF2 as a structure in the defect inspection apparatus 10. In this case, the influence of diffracted light rays can be removed or reduced using both hardware and software, and by suppressing the influence of diffracted light rays that cannot be completely removed or reduced by either method, further improvement in inspection accuracy can be expected. It is also possible to combine this embodiment with not only the first embodiment but also the second embodiment, the third embodiment, or the fourth embodiment.

### Sixth Embodiment

A difference between this embodiment and the first embodiment is that the pattern mask data used in the processing of the first filter is generated based on data obtained by scanning the sample W or a sample of the same type or equivalent as the sample W. In other respects, this embodiment is similar to the first embodiment. Confirmation and adjustment of the validity of pattern mask data can also be performed in the same manner as described in the first embodiment. Further, it is also possible to combine the second to fifth embodiments with this embodiment.

### Outline

In this embodiment, the sample W is inspected using pattern mask data generated based on haze data obtained by scanning the sample. The outline of a procedure for generating pattern mask data and inspecting defects is as follows i) to iii).

### i) Scanning

To generate pattern mask data, first, a sample for mask acquisition is scanned to acquire haze data, which is the basis of pattern mask data. The sample W or a sample of the same type or equivalent as the sample W can be used as the sample for mask acquisition. A more preferable sample for mask acquisition is an inspected sample that is of the same type as the sample W, has undergone the same process as the sample W (sample at the same manufacturing stage during the manufacturing process), and has the number of defects as a product or semi-finished product below an allowable value. Haze data is acquired by post-scanning this inspected sample. In this case, since the light rays from the pattern is high intensity, when there is a concern that sensor damage may occur if the sample for mask acquisition is scanned with the same sensitivity as sample W inspection, the sample for mask acquisition is scanned under lower sensitivity conditions than for sample W inspection.

### ii) Acquisition of Haze Data/Pattern Mask Data

A sample for mask acquisition is scanned, haze (low frequency component) is extracted from the detection signal, and haze data is acquired. In this case, components with low fluctuation frequencies including stationary components are extracted, specifically, components of which values of temporal fluctuation are less than a preset value. These components are candidates for detection signals of light rays generated on the flat surface of the pattern. Pattern mask data can be generated by estimating the die boundaries and coordinates where the pattern exists from the vertical and horizontal (x and y direction) distribution and periodicity (x and y direction pitch) of the coordinates where these components are detected. Haze data can also be acquired from scanning data of a single sample, but in order to acquire more reliable pattern mask data, it is desirable to acquire haze data by integrating the scanning data of a plurality of samples. The pattern mask data is stored in the memory of the signal processing device D or the control device E1, or in the storage device DB.

### iii) Defect Inspection

Next, the sample W is inspected for defects using the pattern mask data. The defect inspection itself is the same as in each of the previously described embodiments, except that pattern mask data obtained by sample scanning is used.

### Pattern Mask Data Generation Processing

FIG. 31 is a functional block diagram illustrating an example of pattern mask data generation processing in a defect inspection apparatus according to a sixth embodiment of the present invention. In this embodiment, the pattern mask data generation processing will be described as being executed by the signal processing device D, but the processing may be executed separately by a computer different from the signal processing device D.

The processing illustrated in FIG. 31 includes processing of sampling f1 and aggregation f2. The processing of sampling f1 and aggregation f2 is performed on the detection signal of each sensor C1 to C13′ in the signal processing device D. The sampling f1 includes processing of low frequency component sampling f1a and high frequency component sampling f1b.

### Low Frequency Component Sampling f1a

In processing of low frequency component sampling f1a, the signal processing device D executes frequency filter (low-pass filter) processing for each detection signal of the sensors C1 to C13′, and extracts components with low fluctuation frequencies including the stationary component. The component with a low fluctuation frequency is a component of which temporal fluctuation is less than a preset value, as described above. By the processing of the low frequency component sampling f1a, detection signals of light rays generated in a region where no pattern is formed or a flat surface of a pattern having a relatively large area are extracted.

### High Frequency Component Sampling f1b

In processing of high frequency component sampling f1b, the signal processing device D executes frequency filter (high-pass filter) processing for each detection signal of the sensors C1 to C13′ to extract components with high fluctuation frequencies. The component with a high fluctuation frequency is a component of which temporal fluctuation exceeds a preset value, as described above. By the processing of the high frequency component sampling f1b, detection signals of light rays generated at defects, isolated patterns, die boundaries, pattern area boundaries, and pattern edges, and random noise and the like are extracted.

### Aggregation f2

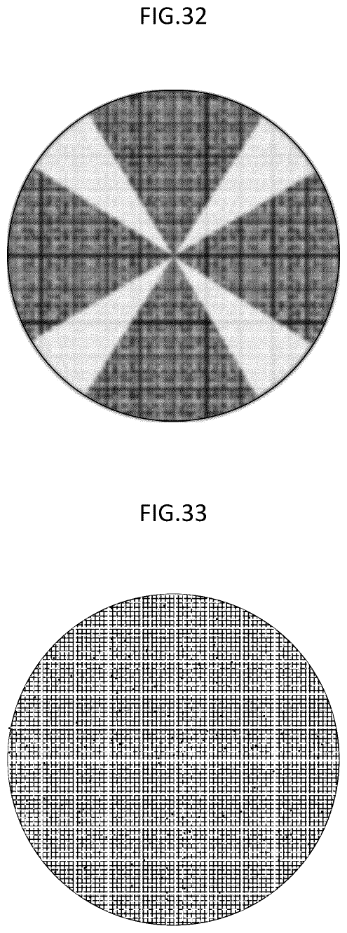

In the processing of aggregation f2, the signal processing device D aggregates the detection signals of the entire surface of the sample W for each sensor C1 to C13′, and acquires data such as haze data and foreign matter map for each sensor C1 to C13′. FIG. 32 is a diagram illustrating an example of haze data. Further, the signal processing device D creates pattern mask data based on the haze data as described above, and stores the pattern mask data in the memory of the signal processing device D or the control device E1, or the storage device DB, for example.

Pattern mask data can be created even from data obtained by scanning a sample as in this embodiment, and as in the previously described embodiments, by using pattern mask data, pattern detection signals can be excluded and the sample W can be inspected with high precision using the rotational scanning method.

### Seventh Embodiment)

A seventh embodiment of the present invention will be described. As similar to the sixth embodiment, this embodiment is an example in which pattern mask data used in the first filter processing is generated based on data obtained by scanning the sample W or a sample of the same type or equivalent as the sample W. However, in the sixth embodiment, pattern mask data is created based on haze data, whereas in this embodiment, pattern mask data is created based on a foreign matter map (high frequency component map). In other respects, this embodiment is similar to the sixth embodiment. Similar to the sixth embodiment, it is also possible to combine this embodiment with the second to fifth embodiments. Confirmation and adjustment of the validity of pattern mask data can be performed in the same manner as in the first embodiment.

For example, as in the high frequency component sampling f1b in the example shown in FIG. 31 above, a foreign matter map can be acquired by scanning the sample W or a sample of the same type or equivalent as the sample W and extracting a high frequency component. FIG. 33 is a diagram illustrating an example of a foreign matter map. In addition to defects, the data on which the foreign matter map is based includes detection signals of light rays generated at isolated patterns, die boundaries, pattern area boundaries, and pattern edges. Therefore, by analyzing the foreign matter map, it is also possible to estimate the die boundaries and pattern coordinates, and create pattern mask data from the estimated die boundaries and pattern coordinates.

The foreign matter map may include data of signals generated by defects as well as signals generated by patterns. Since the number of defects is small, the influence of the inclusion of defect detection signals is small, but it is also possible to exclude signal data generated by defects from the data that is the basis for creating pattern mask data. For example, since the pattern on a patterned wafer has repeatability, it is possible to estimate the boundaries of dies from data on the entire surface of the sample, and compare the dies with each other to estimate and exclude defect detection signals. Further, when scanning data of a plurality of samples (of the same type) for mask acquisition are obtained, it is also possible to estimate and exclude defect detection signals by comparing the scanning data.

In this embodiment as well, as in the previously described embodiments, pattern detection signals are excluded by using pattern mask data, and the sample W can be inspected with high accuracy using the rotational scanning method.

### Modification Example 1

In each embodiment, an example is described in which a signal at a coordinate where the existence of a pattern is estimated is removed by the first filter, but it is also conceivable to uniformly exclude or reduce the detection signal of the sensor among the sensors C1 to C13′ to which the scattered light ray from the pattern is incident. The sensors that allow scattered light rays generated on the flat surface of the pattern to enter or easily enter can be estimated based on the incident angle of the illumination light ray and the detection azimuth angle φ1 and detection zenith angle φ2 of the detection aperture of each detection optical system B1 to B13 with respect to the illumination light ray. When inspecting patterned wafers, the proportion of pattern detection signals is large, so the pattern detection signal can also be removed or reduced by unconditionally removing or reducing the output of the sensor that detects the pattern.

### Modification Example 2

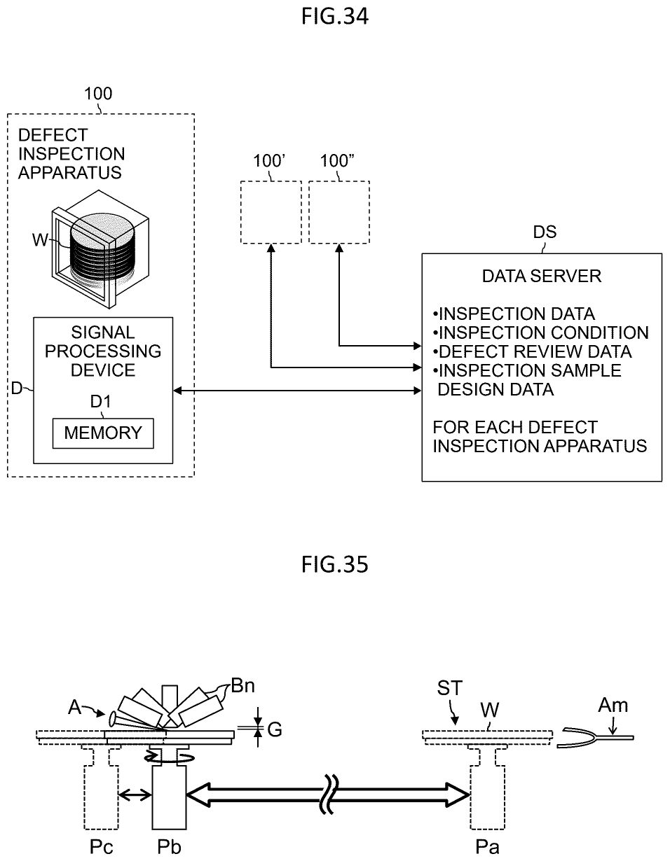

FIG. 34 is a schematic diagram illustrating main parts of a defect inspection apparatus according to a modification example of the present invention. In FIG. 34, elements that are the same as or correspond to those described in each embodiment are given the same reference letters as those in the previous drawings, and the description thereof will be omitted.

This example is an example in which inspection data by a plurality of defect inspection apparatuses is included in the basic data of the above-described filter data (pattern mask data related to the first filter and haze data related to the second filter). In the example illustrated in FIG. 34, the defect inspection apparatus 100 is connected to a data server DS via an appropriate network (not illustrated). Defect inspection apparatuses 100′ and 100″ different from the defect inspection apparatus 100 are connected to this data server DS via an appropriate network. The defect inspection apparatuses 100, 100′, and 100″ are preferably of the same type or equivalent type (same series, same manufacturer, or the like), but may be of different types. Although two other defect inspection apparatuses 100′ and 100″ are illustrated in FIG. 34, the number of other defect inspection apparatuses connected to the data server DS may be one or three or more.

Inspection data is input to the data server DS from the defect inspection apparatuses 100, 100′, and 100″, and these data are accumulated as big data. The accumulated big data includes, for example, sample inspection data, inspection conditions (inspection recipe), defect review data, inspection sample design data, and the like for each defect inspection apparatus. The data server DS calculates filter data such as a first filter (pattern mask data) and a second filter (haze data) regarding the sample W based on these big data. The calculation of the filter data can be performed at regular intervals, or when a certain amount of new data has been accumulated.

In addition, for example, an AI program is introduced to the data server DS, and the filter data can also be automatically updated by the AI program based on inspection data of samples of the same type or equivalent type to the sample W extracted from the big data. Each defect inspection apparatus 100, 100′, 100″ performs a defect inspection on the sample W based on the filter data received from the data server DS. Further, it is also possible to have a configuration in which the inspection data received from each defect inspection apparatus 100, 100′, 100″ is processed by the data server DS to perform defect inspection, and the inspection results are displayed on the monitor of the data server DS or sent back to the defect inspection apparatus 100, 100′, 100″.

According to this example, in addition to the own inspection data of the defect inspection apparatus 100, the filter data is calculated using a large number of inspection data from other defect inspection apparatuses 100 and 100′ as basic data, so this has an advantage that inspection accuracy can be improved as basic data is accumulated.

### Modification Example 3

FIG. 35 is a schematic diagram illustrating main parts of a defect inspection apparatus according to another modification example of the present invention. In FIG. 35, elements that are the same as or correspond to those described in the first embodiment are given the same reference letters as those in the previous drawings, and the description thereof will be omitted.

This example is a variation of the method for acquiring basic data of filter data. On a movement axis of the translation stage of the stage ST, a sample delivery position Pa, an inspection start position Pb, and an inspection completion position Pc are set, and by driving the translation stage, the stage ST moves along a straight line passing through these positions. The inspection start position Pb is a position where the sample W is irradiated with illumination light rays to start inspection of the sample W, and is a position where a center of the sample W matches the illumination spot BS of the illumination optical system A. The inspection completion position Pc is a position where the inspection of the sample W is completed, and in this example, is a position where an outer edge of the sample W matches the illumination spot BS. The sample delivery position Pa is a position where the sample W is attached to and removed from (loading and unloading) the stage ST by an arm Am, and the stage ST, which has received the sample W, moves from the sample delivery position Pa to the inspection start position Pb. Due to the recent demand for even more sensitive inspection, the detection optical systems B1 to B13 are arranged close to the sample W, and when the stage ST is located directly below the detection optical systems B1 to B13, a gap G between the stage ST and the detection optical systems B1 to B13 is about several mm or less. Since it is difficult to insert the sample W into the gap G and place the sample on the stage ST using the arm Am at the inspection start position Pb, a configuration is adopted in which the sample W is delivered at the sample delivery position Pa that is distant from the inspection start position Pb.

The illumination light ray is applied to the sample and the sample W is scanned while the stage ST is moving from the inspection start position Pb to the inspection completion position Pc, but in this example, the preliminary scan is performed while the stage ST moves from the sample delivery position Pa to the inspection start position Pb. The data obtained through this preliminary scanning is then used as basic data for filter data. In this example, when inspecting the sample W from the center toward the outer periphery, the sample W is scanned in a spiral trajectory from the outer periphery toward the center in the preliminary scan.

According to this example, the transport operation of the sample W can be used to collect basic data of filter data, and the efficiency of collecting basic data can be improved. Filter data can be created or updated every time a preliminary scan is performed.

### Others

As described above, the defect inspection apparatus 100 can also perform defect inspection using vertical illumination. The vertical illumination enters the sample W perpendicularly, and a specularly reflected light ray also exits perpendicularly from the sample W (along the normal line N in FIG. 25). Therefore, unlike the case where oblique incidence illumination is used, the zenith of the celestial sphere where the detection apertures of the detection optical systems B1 to B13 are arranged becomes the origin of the frequency of the Fourier transform, and the distribution line of the incident points of diffracted light ray on the celestial sphere rotates around the zenith in plan view. Therefore, the algorithm of the second filter as program processing can be simplified.

Further, when creating filter data, if a large proportion of data is acquired while the illumination spot BS straddles a pattern edge during sample scanning, the accuracy of the filter data may decrease. Therefore, when scanning a sample to create filter data, it is advantageous to make the illumination spot BS small in order to acquire highly accurate filter data.

In addition, although the outputs of the sensors C1 to C13′ are described as detection signals, the detection signal may include a composite signal of a subset of the output signals of the sensors C1 to C13′ instead of or in addition to all or part of the outputs of the sensors C1 to C13′. By combining the output signals of the plurality of sensors and treating the combined signal as a single detection signal, it is possible to reduce the amount of data to be processed and stored, and it is also possible to increase the S/N ratio by summing up weak defect signals.

In addition, although the order of execution of the first filter and the second filter as program processing is efficient in the order of the first filter and the second filter, but the execution order may be reversed, or the processing of the first filter and the second filter may be combined.

### REFERENCE SIGNS LIST

100: defect inspection apparatus
A: illumination optical system
B1 to B13, Bn: detection optical system
C1 to C13, C1′ to C13′: sensor
D: signal processing device
GT: gain table (second filter)
PM: pattern mask data (first filter)
S14: first filter
S15: second filter
S24: first filter
S25: second filter
SF1: spatial filter (second filter)
SF2: second filter
ST1: sample stand
ST2: scanning device
W: sample

1. A defect inspection apparatus that inspects a sample with a structure repeatedly formed on a surface, comprising:
a sample stand supporting the sample;
an illumination optical system that irradiates the sample placed on the sample stand with an illumination light ray;
a scanning device that rotationally drives the sample stand to change a relative position of the sample and the illumination optical system;
a plurality of detection optical systems that collect light rays from the surface of the sample;
a plurality of sensors that convert the light rays collected by the corresponding detection optical systems into electrical signals and output detection signals;
a signal device processing that processes the detection signals of the plurality of sensors to detect a defect in the sample;
a first filter that removes or reduces the detection signals of the structure; and
a second filter that removes or reduces diffracted light rays generated by the structure or detection signals of the diffracted light rays according to a θ coordinate of a circular coordinate system of the sample or at a set period.

2. The defect inspection apparatus according to claim 1, wherein
the sample is a patterned wafer.

3. The defect inspection apparatus according to claim 1, wherein
the second filter is program processing by the signal processing device that removes or reduces each detection signal of the plurality of sensors according to the 0 coordinate or at the set period to remove or reduce the detection signals of the diffracted light rays.

4. The defect inspection apparatus according to claim 1, wherein
the second filter is program processing executed by the signal processing device that removes or reduces the detection signals of the diffracted light rays by changing gains of the plurality of sensors according to the θ coordinate or at the set period.

5. The defect inspection apparatus according to claim 1, wherein
the second filter is a mechanical filter placed in each Fourier space of the plurality of detection optical systems, and is configured to rotate in synchronization with the sample stand and block the diffracted light rays generated by the structure.

6. The defect inspection apparatus according to claim 1, wherein
the second filter is a static shielding structure that partially blocks detection optical paths of at least some of the plurality of detection optical systems so that the number of detection optical systems to which the diffracted light rays generated by the structure are simultaneously incident is reduced.

7. The defect inspection apparatus according to claim 1, wherein
the first filter is program processing executed by the signal processing device that removes or reduces detection signals at coordinates where the structure is located based on pattern mask data corresponding to a position of the structure on the surface of the sample.

8. The defect inspection apparatus according to claim 7, wherein
the pattern mask data is based on design data of the sample.

9. The defect inspection apparatus according to claim 7, wherein
the pattern mask data is based on data obtained by scanning the sample or a sample of the same type or equivalent as the sample.

10. A defect inspection method for inspecting a sample with a structure repeatedly formed on a surface using a defect inspection apparatus including a sample stand supporting the sample, an illumination optical system that irradiates the sample placed on the sample stand with an illumination light ray, a scanning device that rotationally drives the sample stand to change a relative position of the sample and the illumination optical system, a plurality of detection optical systems that collect light rays from the surface of the sample, a plurality of sensors that convert the light rays collected by the corresponding detection optical systems into electrical signals and output detection signals, a signal processing device that processes the detection signals of the plurality of sensors to detect a defect in the sample, the defect inspection method comprising:
removing or reducing the detection signals of the structure; and
removing or reducing diffracted light rays generated by the structure or detection signals of the diffracted light rays according to a θ coordinate of a circular coordinate system of the sample or at a set period.
